(19) United States
(12) Patent Application Publication
(10) Pub. No.: US 2026/0371759 A1
(43) Pub. Date: Nov. 19, 2026

(54) PHOTODETECTOR AND ELECTRONIC APPARATUS

(71) Applicant: SONY SEMICONDUCTOR SOLUTIONS CORPORATION, Kanagawa (JP)

(72) Inventors: Tatsuki HINAMOTO, Osaka (JP); Mayu MOTOHASHI, Kanagawa (JP); Takuro MURASE, Kanagawa (JP)

(73) Assignee: SONY SEMICONDUCTOR SOLUTIONS CORPORATION, Kanagawa (JP)

(21) Appl. No.: 19/135,709

(22) PCT Filed: Nov. 13, 2023
(86) PCT No.: PCT/JP2023/040754

§ 371 Date: Jun. 4, 2025

(30) Foreign Application Priority Data
Dec. 27, 2022 (JP) 2022-210859

(51) Int. Cl. H10F 39/00; H10F 39/12; H10F 39/18

(52) U.S. Cl. CPC H10F 39/8053; H10F 39/182; H10F 39/199; H10F 39/802

(57) ABSTRACT

An imaging device, an electronic apparatus and method of manufacturing the same is provided to efficiently condense incident light. The imaging device includes a semiconductor layer including a plurality of light-receiving sections, wherein a color filter is disposed above each of the plurality of light-receiving sections. The imaging device also includes a plurality of light-guiding walls provided between color filters. The imaging device also includes a plurality of structures configured to guide incident light to the plurality of light-receiving sections, wherein the plurality of structures are provided on a light incident side of the semiconductor layer.

### CROSS REFERENCE TO RELATED APPLICATIONS

This application claims the benefit of Japanese Priority Patent Application JP2022-210859 filed Dec. 27, 2022, the entire contents of which are incorporated herein by reference.

### TECHNICAL FIELD

The present disclosure relates to a photodetector and an electronic apparatus.

### BACKGROUND ART

A device has been proposed in which a light-blocking film that prevents leakage of incident light into neighboring pixels and a low refractive index film stacked on the light-blocking film are formed at a pixel boundary part on a semiconductor substrate (PTL 1).

### CITATION LIST

### Patent Literature

[PTL 1] Japanese Unexamined Patent Application Publication No. 2021-158374

### SUMMARY

### Technical Problem

It is desired, for a device that detects light, to make it possible to efficiently condense incident light.

It is desirable to provide a photodetector that makes it possible to efficiently condense light.

### BRIEF DESCRIPTION OF DRAWINGS

FIG. 1 is a block diagram illustrating an example of a schematic configuration of an imaging device which is an example of a photodetector according to an embodiment of the present disclosure.

FIG. 2 is a diagram illustrating an example of a pixel section of the imaging device according to the embodiment of the present disclosure.

FIG. 3 is a diagram illustrating a configuration example of a pixel of the imaging device according to the embodiment of the present disclosure.

FIG. 4 is a diagram illustrating an example of a planar configuration of the imaging device according to the embodiment of the present disclosure.

FIG. 5 is a diagram illustrating an example of a cross-sectional configuration of the imaging device according to the embodiment of the present disclosure.

FIG. 6 is a diagram illustrating a configuration example of an imaging device according to a comparative example.

FIG. 7 is a diagram illustrating a configuration example of the imaging device according to the embodiment of the present disclosure.

FIG. 8 is a diagram illustrating a configuration example of the imaging device according to the embodiment of the present disclosure.

FIG. 9 is a diagram illustrating another configuration example of the imaging device according to the embodiment of the present disclosure.

FIG. 10 is a diagram illustrating another configuration example of the imaging device according to the embodiment of the present disclosure.

FIG. 11A is a diagram illustrating an example of a method of manufacturing the imaging device according to the embodiment of the present disclosure.

FIG. 11B is a diagram illustrating an example of the method of manufacturing the imaging device according to the embodiment of the present disclosure.

FIG. 11C is a diagram illustrating an example of the method of manufacturing the imaging device according to the embodiment of the present disclosure.

FIG. 11D is a diagram illustrating an example of the method of manufacturing the imaging device according to the embodiment of the present disclosure.

FIG. 11E is a diagram illustrating an example of the method of manufacturing the imaging device according to the embodiment of the present disclosure.

FIG. 11F is a diagram illustrating an example of the method of manufacturing the imaging device according to the embodiment of the present disclosure.

FIG. 12 is a diagram illustrating an example of a cross-sectional configuration of an imaging device according to Modification Example 1 of the present disclosure.

FIG. 13A is a diagram illustrating another example of the cross-sectional configuration of the imaging device according to Modification Example 1 of the present disclosure.

FIG. 13B is a diagram illustrating another example of the cross-sectional configuration of the imaging device according to Modification Example 1 of the present disclosure.

FIG. 13C is a diagram illustrating another example of the cross-sectional configuration of the imaging device according to Modification Example 1 of the present disclosure.

FIG. 13D is a diagram illustrating another example of the cross-sectional configuration of the imaging device according to Modification Example 1 of the present disclosure.

FIG. 14A is a diagram illustrating an example of a planar configuration of an imaging device according to Modification Example 2 of the present disclosure.

FIG. 14B is a diagram illustrating an example of the planar configuration of the imaging device according to Modification Example 2 of the present disclosure.

FIG. 14C is a diagram illustrating an example of the planar configuration of the imaging device according to Modification Example 2 of the present disclosure.

FIG. 14D is a diagram illustrating an example of the planar configuration of the imaging device according to Modification Example 2 of the present disclosure.

FIG. 15A is a diagram illustrating an example of a planar configuration of an imaging device according to Modification Example 3 of the present disclosure.

FIG. 15B is a diagram illustrating an example of the planar configuration of the imaging device according to Modification Example 3 of the present disclosure.

FIG. 16 is a diagram illustrating an example of a planar configuration of an imaging device according to Modification Example 4 of the present disclosure.

FIG. 17 is a diagram illustrating another example of the planar configuration of the imaging device according to Modification Example 4 of the present disclosure.

FIG. 18A is a diagram illustrating an example of a cross-sectional configuration of an imaging device according to Modification Example 5 of the present disclosure.

FIG. 18B is a diagram illustrating an example of the cross-sectional configuration of the imaging device according to Modification Example 5 of the present disclosure.

FIG. 19A is a diagram illustrating another example of the cross-sectional configuration of the imaging device according to Modification Example 5 of the present disclosure.

FIG. 19B is a diagram illustrating another example of the cross-sectional configuration of the imaging device according to Modification Example 5 of the present disclosure.

FIG. 20 is a diagram illustrating an example of a cross-sectional configuration of an imaging device according to Modification Example 6 of the present disclosure.

FIG. 21 is a diagram illustrating an example of a planar configuration of the imaging device according to Modification Example 6 of the present disclosure.

FIG. 22 is a diagram illustrating another example of the planar configuration of the imaging device according to Modification Example 6 of the present disclosure.

FIG. 23 is a diagram illustrating another example of the cross-sectional configuration of the imaging device according to Modification Example 6 of the present disclosure.

FIG. 24 is a diagram illustrating another example of the planar configuration of the imaging device according to Modification Example 6 of the present disclosure.

FIG. 25 is a diagram illustrating another example of the planar configuration of the imaging device according to Modification Example 6 of the present disclosure.

FIG. 26 is a diagram illustrating a configuration example of a pixel of an imaging device according to Modification Example 7 of the present disclosure.

FIG. 27 is a block diagram illustrating a configuration example of an electronic apparatus including the imaging device.

FIG. 28 is a block diagram depicting an example of schematic configuration of a vehicle control system.

FIG. 29 is a diagram of assistance in explaining an example of installation positions of an outside-vehicle information detecting section and an imaging section.

FIG. 30 is a view depicting an example of a schematic configuration of an endoscopic surgery system.

FIG. 31 is a block diagram depicting an example of a functional configuration of a camera head and a camera control unit (CCU).

### DESCRIPTION OF EMBODIMENTS

Hereinafter, a description is given in detail of embodiments of the present disclosure with reference to the drawings. It is to be noted that the description is given in the following order.
1. Embodiment
2. Modification Examples
3. Application Example
4. Practical Application Examples

### 1. Embodiment

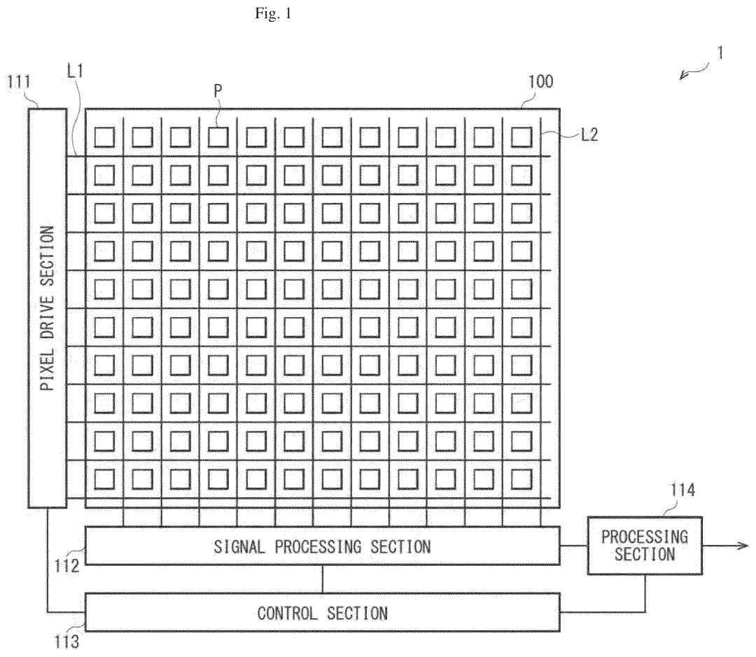

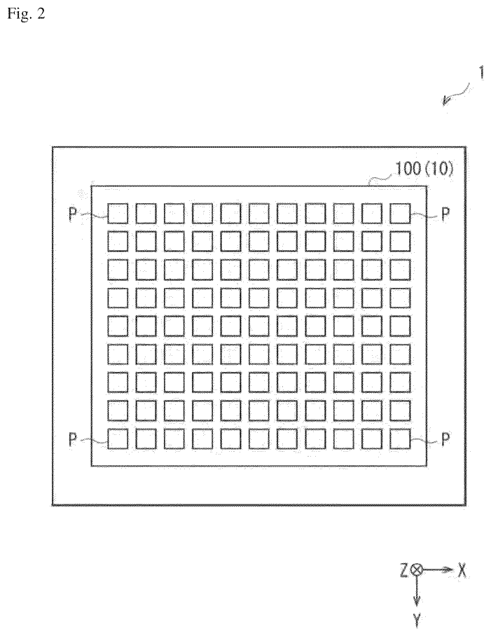

FIG. 1 is a block diagram illustrating an example of a schematic configuration of an imaging device which is an example of a photodetector according to an embodiment of the present disclosure. FIG. 2 is a diagram illustrating an example of a pixel section of the imaging device according to the embodiment. The photodetector is a device that is able to detect incoming light. An imaging device 1, which is a photodetector, includes a plurality of pixels P each including a light-receiving section (light-receiving element), and is configured to photoelectrically convert incident light and generate a signal. The imaging device 1 (photodetector) can receive light transmitted through an optical system including an optical lens and generate a signal.

The light-receiving section of each of the pixels P of the imaging device 1 is, for example, a photodiode, and is configured to be able to photoelectrically convert light. As illustrated in FIG. 2, the imaging device 1 includes, as an imaging area, a region (a pixel section 100) in which the plurality of pixels P are two-dimensionally arranged in matrix. The pixel section 100 can also be referred to as a pixel array in which the plurality of pixels P are arranged.

The imaging device 1 takes in incident light (image light) from a subject via an optical system (unillustrated) including an optical lens. The imaging device 1 captures an image of the subject formed by the optical lens. The imaging device 1 can photo-electrically convert received light to generate a pixel signal. The imaging device 1 is, for example, a CMOS (Complementary Metal Oxide Semiconductor) image sensor. The imaging device 1 is usable for an electronic apparatus such as a digital still camera, a video camera, or a mobile phone.

It is to be noted that, as illustrated in FIG. 2, a direction in which light from the subject is incident is defined as a Z-axis direction; a right-left direction on the sheet orthogonal to the Z-axis direction is defined as an X-axis direction; and an up-down direction on the sheet orthogonal to the Z-axis direction and the X-axis direction is defined as a Y-axis direction. In the following drawings, the arrow directions in FIG. 2 may be used, in some cases, as a standard to express a direction.

### Schematic Configuration of Imaging Device

As in the example illustrated in FIG. 1, the imaging device 1 includes, in a peripheral region of the pixel section 100 (pixel array), for example, a pixel drive section 111, a signal processing section 112, a control section 113, a processing section 114, and the like. In addition, the imaging device 1 is provided with a plurality of control lines L1 and a plurality of signal lines L2.

The control line L1 is a signal line that is able to transmit a signal to control the pixel P, and is coupled to the pixel drive section 111 and the pixels P of the pixel section 100. In the pixel section 100, in the example illustrated in FIG. 1, the plurality of control lines L1 are wired for respective pixel rows each configured by the plurality of pixels P arranged in a horizontal direction (row direction). The control line L1 is configured to transmit a control signal to read a signal from the pixel P.

The plurality of control lines L1 for respective pixel rows of the imaging device 1 includes a wiring line that transmits a signal to control a transfer transistor, a wiring line that transmits a signal to control a selection transistor, a wiring line that transmits a signal to control a reset transistor, and the like. The control line L1 can also be referred to as a drive line (pixel drive line) that transmits a signal to drive the pixel P.

The signal line L2 is a signal line that is able to transmit a signal from the pixel P, and is coupled to the pixels P of the pixel section 100 and the signal processing section 112. In the pixel section 100, for example, signal lines L2 are wired for respective pixel columns each configured by a plurality of pixels P arranged in a vertical direction (column direction). The signal line L2 is a vertical signal line, and is configured to transmit a signal outputted from the pixel P.

The pixel drive section 111 is configured to be able to drive each of the pixels P of the pixel section 100. The pixel drive section 111 is a drive circuit, and is configured by a buffer, a shift register, an address decoder, and the like. The pixel drive section 111 generates a signal to drive the pixel P, and outputs the signal to each of the pixels P of the pixel section 100 via the control line L1. The pixel drive section 111 is controlled by the control section 113, and controls the pixels P of the pixel section 100.

The pixel drive section 111 generates, for example, a signal to the control the pixel P, such as a signal to control the transfer transistor of the pixel P and a signal to control the reset transistor, and supplies the signal to each of the pixels P by the control line L1. The pixel drive section 111 can perform control to read a pixel signal from each of the pixels P. The pixel drive section 111 may also be referred to as a pixel control section configured to be able to control each of the pixels P. It is to be noted that the pixel drive section 111 and the control section 113 can also be collectively referred to as a pixel control section.

The signal processing section 112 is configured to be able to execute signal processing of an inputted pixel signal. The signal processing section 112 is a signal processing circuit, and includes, for example, a load circuit part, an AD (Analog-to-Digital) converter part, a horizontal selection switch, and the like. It is to be noted that the signal processing section 112 may include an amplification circuit part configured to amplify a signal read from the pixel P via the signal line L2.

The signal output from each of the pixels P selected and scanned by the pixel drive section 111 is inputted to the signal processing section 112 via the signal line L2. The signal processing section 112 can perform, for example, signal processing such as CDS (Correlated Double Sampling: correlated double sampling) and AD conversion of the signal of the pixel P. The signal of each of the pixels P transmitted through each of the signal lines L2 is subjected to signal processing by the signal processing section 112, and outputted to the processing section 114.

The processing section 114 is configured to be able to execute signal processing on an inputted signal. The processing section 114 is a signal processing circuit, and is configured by, for example, a circuit that performs various types of signal processing on a pixel signal. The processing section 114 may include a processor and a memory. The processing section 114 performs signal processing on the pixel signal input from the signal processing section 112, and outputs the processed pixel signal. The processing section 114 can perform, for example, various types of signal processing such as noise reduction processing or gradation correction processing.

The control section 113 is configured to be able to control each section of the imaging device 1. The control section 113 can receive a clock supplied from the outside, data ordering an operation mode, or the like, and output data such as internal information on the imaging device 1. The control section 113 is a control circuit, and includes, for example, a timing generator configured to be able to generate various timing signals. The control section 113 controls driving of the pixel drive section 111, the signal processing section 112, and the like on the basis of the various timing signals (pulse signals, clock signals, and the like) generated by the timing generator. It is to be noted that the control section 113 and the processing section 114 may be integrally configured.

The pixel drive section 111, the signal processing section 112, the control section 113, the processing section 114, and the like may be provided in one semiconductor substrate or may be provided separately in a plurality of semiconductor substrates. The imaging device 1 may have a structure (stacked structure) configured by stacking a plurality of substrates.

### Configuration of Pixel

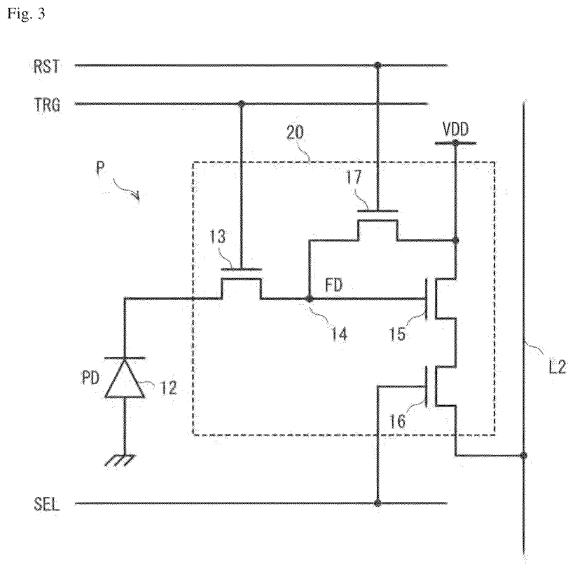

FIG. 3 is a diagram illustrating a configuration example of a pixel of an imaging device according to the embodiment. The pixel P includes a light-receiving section 12 (light-receiving element) and a readout circuit 20. The readout circuit 20 is configured to be able to output a signal based on electric charge having undergone photoelectric conversion. As an example, the readout circuit 20 includes a transfer transistor 13, an FD (floating diffusion) 14, an amplification transistor 15, a selection transistor 16, and a reset transistor 17.

The transfer transistor 13, the amplification transistor 15, the selection transistor 16, and the reset transistor 17 are each an MOS transistor (MOSFET) including terminals of a gate, a source, and a drain. In the example illustrated in FIG. 3, the transfer transistor 13, the amplification transistor 15, the selection transistor 16, and the reset transistor 17 are each configured by an NMOS transistor. It is to be noted that the transistor of the pixel P may be configured by a PMOS transistor.

The light-receiving section 12 is configured to receive light and generate a signal. The light-receiving section 12 is a photoelectric conversion element (photoelectric conversion section), and is configured to be able to generate electric charge by photoelectric conversion. In the example illustrated in FIG. 3, the light-receiving section 12 is a photodiode (PD), and converts incoming light into electric charge. The light-receiving section 12 performs photoelectric conversion to generate electric charge corresponding to a received light amount.

The transfer transistor 13 is configured to be able to transfer the electric charge photoelectrically converted by the light-receiving section 12 to the FD 14. As illustrated in FIG. 3, the transfer transistor 13 is controlled by a signal TRG to electrically couple or decouple the light-receiving section 12 and the FD 14 to or from each other. The transfer transistor 13 can transfer electric charge photoelectrically converted and accumulated by the light-receiving section 12 to the FD 14.

The FD 14 is an accumulation section, and is configured to be able to accumulate the transferred electric charge. The FD 14 can accumulate electric charge photoelectrically converted by the light-receiving section 12. The FD 14 can also be referred to as a holding section that is able to hold the transferred electric charge. The FD 14 accumulates and converts the transferred electric charge into a voltage corresponding to a capacity of the FD 14.

The amplification transistor 15 is configured to generate and output a signal based on the electric charge accumulated in the FD 14. As illustrated in FIG. 3, a gate of the amplification transistor 15 is electrically coupled to the FD 14 to allow the voltage converted by the FD 14 to be input thereto. A drain of the amplification transistor 15 is coupled to a power supply line to be supplied with a power supply voltage VDD, and a source of the amplification transistor 15 is coupled to the signal line L2 via the selection transistor 16. The amplification transistor 15 can generate a signal based on the electric charge accumulated in the FD 14, i.e., a signal based on the voltage of the FD 14, and output the generated signal to the signal line L2.

The selection transistor 16 is configured to be able to control the output of a pixel signal. The selection transistor 16 is controlled by a signal SEL, and is configured to be able to output the signal from the amplification transistor 15 to the signal line L2. The selection transistor 16 can control an output timing of the pixel signal. It is to be noted that the selection transistor 16 may be provided between the power supply line to be supplied with the power supply voltage VDD and the amplification transistor 15. In addition, the selection transistor 16 may be omitted, as needed.

The reset transistor 17 is configured to be able to reset the voltage of the FD 14. In the example illustrated in FIG. 3, the reset transistor 17 is electrically coupled to the power supply line to be supplied with the power supply voltage VDD, and is configured to reset electric charge of the pixel P. The reset transistor 17 can be controlled by a signal RST to reset the electric charge accumulated in the FD 14 and to reset the voltage of the FD 14. It is to be noted that the reset transistor 17 can discharge the electric charge accumulated in the light-receiving section 12 via the transfer transistor 13.

The pixel drive section 111 (see FIG. 1) supplies a control signal to the gates of the transfer transistor 13, the selection transistor 16, the reset transistor 17, and the like of each of the pixels P via the above-described control line L1, to bring the transistors into an ON state (an electrically-conductive state) or an OFF state (a non-electrically-conductive state). The plurality of control lines L1 of the imaging device 1 includes a wiring line that transmits the signal TRG to control the transfer transistor 13, a wiring line that transmits the signal SEL to control the selection transistor 16, a wiring line that transmits the signal RST to control the reset transistor 17, and the like.

The transfer transistor 13, the selection transistor 16, the reset transistor 17, and the like are controlled to be turned ON or OFF by the pixel drive section 111. The pixel drive section 111 controls the readout circuit 20 of each of the pixels P to thereby cause each of the pixels P to output a pixel signal to the signal line L2. The pixel drive section 111 can perform control to read the pixel signal of each of the pixels P to the signal line L2.

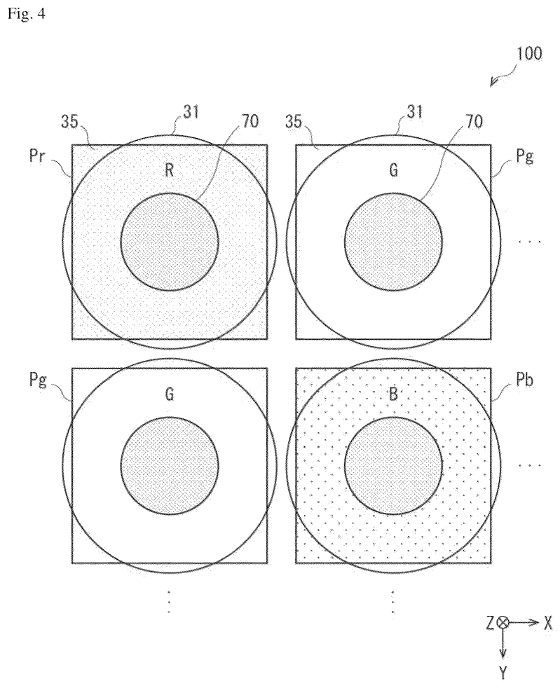

FIG. 4 is a diagram illustrating an example of a planar configuration of the imaging device according to the embodiment. FIG. 4 illustrates an example of an arrangement of the pixels P of the pixel section 100 of the imaging device 1. The pixel P of the imaging device 1 includes a lens section 31 and a filter 35. In addition, the pixel P includes a structure 70 which is a fine structure, as described later.

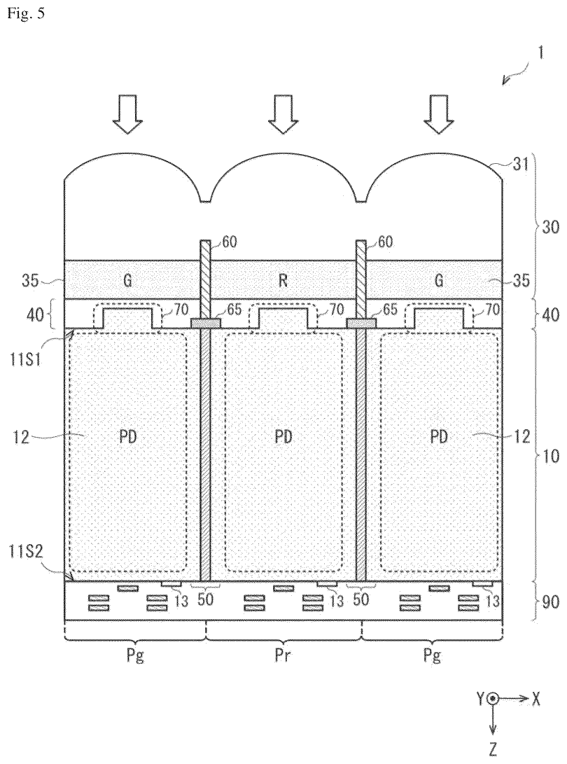

The lens section 31 guides incoming light to a side of the light-receiving section 12 of the pixel P (see FIG. 5 or other drawings described later). The lens section 31 is an optical member also called an on-chip lens. The lens section 31 is provided, for example, for each pixel P or for each plurality of pixels P. Light from a subject is incident on the lens section 31 via an optical system such as an imaging lens. The light-receiving section 12 photoelectrically converts light incident via the lens section 31 and the filter 35.

The filter 35 is configured to selectively transmit light of a particular wavelength region of the incoming light. The filter 35 is a color filter of RGB, a filter that transmits infrared light, or the like. The plurality of pixels P provided in the pixel section 100 of the imaging device 1 includes a plurality of pixels Pr provided with the filter 35 that transmits red (R) light, a plurality of pixels Pg provided with the filter 35 that transmits green (G) light, and a plurality of pixels Pb provided with the filter 35 that transmits blue (B) light.

In the pixel section 100, as in the example illustrated in FIG. 4, the plurality of pixels Pr, the plurality of pixels Pg, and the plurality of pixels Pb are repeatedly arranged. The pixel Pr, the pixel Pg, and the pixel Pb are arranged in accordance with Bayer arrangement, for example. The pixel Pr, the pixel Pg, and the pixel Pb generate a pixel signal of an R component, a pixel signal of a G component, and a pixel signal of a B component, respectively. The imaging device 1 is able to obtain pixel signals of RGB.

It is to be noted that the filter 35 provided for the pixels P of the pixel section 100 is not limited to a color filter of a primary color system (RGB), and may be a color filter of a complementary color system such as Cy (cyan), Mg (magenta), or Ye (yellow), for example. In the pixel P that receives white (W) light to perform photoelectric conversion, the filter 35 may not be provided. In addition, a filter corresponding to W (white), i.e., a filter that transmits light beams of all wavelength regions of incident light may be arranged. It is to be noted that the filter 35 may be omitted, as needed. For example, depending on characteristics of the structure 70, the filter 35 may not be provided for some or all of the pixels P of the imaging device 1.

FIG. 5 is a diagram illustrating an example of a cross-sectional configuration of an imaging device according to the embodiment. As illustrated in FIG. 5, the imaging device 1 has a configuration in which, for example, a light-guiding section 30, an insulating layer 40, a semiconductor layer 10, and a multilayer wiring layer 90 are stacked in the Z-axis direction. In the example illustrated in FIG. 5, the light-guiding section 30 is provided on a side on which light from an optical system is incident, and the multilayer wiring layer 90 is provided on a side opposite to the side on which light is incident. The imaging device 1 is a so-called back-illuminated imaging device.

As illustrated in FIG. 5, the semiconductor layer 10 has a first surface 11S1 and a second surface 11S2 opposed to each other. The second surface 11S2 is a surface on a side opposite to the first surface 11S1. The semiconductor layer 10 is configured by, for example, a Si (silicone) substrate. The first surface 11S1 of the semiconductor layer 10 is light-receiving surface (light incident surface). The second surface 11S2 of the semiconductor layer 10 is an element formation surface on which an element such as a transistor is formed. The second surface 11S2 of the semiconductor layer 10 can be provided with a gate electrode, a gate oxide film, and the like.

In the semiconductor layer 10, a plurality of light-receiving sections 12 (light-receiving elements) are provided along the first surface 11S1 and the second surface 11S2 of the semiconductor layer 10. It is to be noted that the semiconductor layer 10 may be an SOI (Silicon On Insulator) substrate, an SiGe (silicon germanium) substrate, an SiC substrate, or the like, and may be configured by a Group III-V compound semiconductor material, or the like.

The multilayer wiring layer 90 includes, for example, a conductor film and an insulating film, and includes a plurality of wiring line, vias (VIA), and the like. The multilayer wiring layer 90 includes, for example, two or more layers of wiring lines. The multilayer wiring layer 90 has a configuration in which a plurality of wiring lines are stacked with the insulating film interposed therebetween. This insulating film can also be referred to as an interlayer insulating film (interlayer insulating layer).

The wiring line of the multilayer wiring layer 90 is formed using a metal material such as aluminum (Al), copper (Cu), or tungsten (W). The wiring line of the multilayer wiring layer 90 may be configured using polysilicon (Poly-Si) or another electrically-conductive material. The interlayer insulating film is formed using, for example, silicon oxide (SiO), silicon nitride (SiN), silicon oxynitride (SiON), or the like.

The semiconductor layer 10 and the multilayer wiring layer 90 are provided with, for example, the readout circuit 20 described above. FIG. 5 schematically illustrates a gate electrode of the transfer transistor 13. It is to be noted that the pixel drive section 111, the signal processing section 112, the control section 113, the processing section 114, and the like described above can be formed in a substrate different from the semiconductor layer 10, or in the semiconductor layer 10 and the multilayer wiring layer 90.

The light-guiding section 30 is stacked on the insulating layer 40 and the semiconductor layer 10 in a thickness direction orthogonal to the first surface 11S1 of the semiconductor layer 10. The light-guiding section 30 includes the lens section 31 and the filter 35, and guides light incident from above to a side of the semiconductor layer 10.

The insulating layer 40 is provided between a layer provided with the light-receiving section 12 and a layer provided with the filter 35. The insulating layer 40 is provided to be stacked on the semiconductor layer 10, and is positioned on the first surface 11S1 of the semiconductor layer 10. The insulating layer 40 is formed using, for example, an insulating film such as an oxide film, a nitride film, or an oxynitride film.

The insulating layer 40 may be configured by silicon oxide (SiO), silicon nitride (SiN), silicon oxynitride (SiON), and the like, or may be configured using another insulating material. The insulating layer 40 may also be referred to as a planarization layer (planarization film).

As illustrated in FIG. 5, the imaging device 1 is provided with a separation section 50, a light-guiding wall 60, a light-blocking section 65, and the structure 70. The separation section 50 is provided between the plurality of light-receiving sections 12 adjacent to each other to separate the light-receiving sections 12 from each other. The separation section 50 is provided to surround the light-receiving section 12 in the semiconductor layer 10, for example. The separation section 50 has a trench (groove) provided at a boundary between the pixels P (or the light-receiving sections 12) adjacent to each other.

The separation section 50 including the trench can be provided to penetrate the semiconductor layer 10, for example, as in the example illustrated in FIG. 5. As an example, an insulating film, e.g., a silicone oxide film is provided inside the trench of the separation section 50. It is to be noted that polysilicon, a metal material, or the like may be embedded in the trench of the separation section 50. The separation section 50 may be formed using another dielectric material having a low refractive index. For example, an air gap (cavity) may be provided inside the trench of the separation section 50. Providing the separation section 50 suppresses leakage of light to surrounding pixels P.

The light-guiding wall 60 is provided between the filters 35 adjacent to each other. The light-guiding wall 60 is provided to surround, for example, four sides of the filter 35. As in the example illustrated in FIG. 5, the light-guiding wall 60 is a wall-shaped structure. The light-guiding wall 60 is positioned at the sides of the filter 35, and has a refractive index lower than a refractive index of a surrounding medium. The light-guiding wall 60 has a refractive index lower than a refractive index of the filter 35. The light-guiding wall 60 is provided at a boundary between the pixels P adjacent to each other, and can also be referred to as a separation wall (or separation section) that separates the filters 35 from each other.

The light-guiding wall 60 is configured by, for example, silicon oxide, air gap (cavity), or the like. It is to be noted that the light-guiding wall 60 may be formed using another dielectric material having a low refractive index. The light-guiding wall 60 may be configured using an organic material. The light-guiding wall 60 changes a direction in which incident light travels by a refractive index difference between the light-guiding wall 60 and the surrounding medium. Providing the light-guiding wall 60 suppresses light leakage into surrounding pixels, thus reducing color mixture.

The light-blocking section 65 (light-blocking film) is configured by a member that blocks light, and is provided at a boundary between the plurality of pixels P adjacent to each other. The light-blocking section 65 (light-blocking member) is provided for the bottom of the light-guiding wall 60, for example, inside the insulating layer 40 or on the insulating layer 40. The light-blocking section 65 is positioned above the separation section 50 in the example illustrated in FIG. 5. In addition, for example, the light-blocking section 65 can be provided between the filters 35 adjacent to each other, and can be positioned at the boundary between the filters 35 adjacent to each other.

The light-blocking section 65 is configured by, for example, a metal material (aluminum (Al), tungsten (W), copper (Cu), etc.) that blocks light. The light-blocking section 65 may be configured by a material that absorbs light. The light-blocking section 65 is provided around the light-receiving section 12 to suppress leakage of light to surrounding pixels.

It is to be noted that the imaging device 1 may include a fixed charge film and an antireflection film. The fixed charge film and the antireflection film are provided between the semiconductor layer 10 and the insulating layer 40, for example. As an example, the fixed charge film is configured by a metal compound (metal oxide, metal nitride, etc.). The fixed charge film is, for example, a film having negative fixed electric charge, and suppresses generation of a dark current at an interface of the semiconductor layer 10.

The imaging device 1 includes the structure 70, and is configured to guide incident light to the side of the light-receiving section 12. The structure 70 is provided on a side of the first surface 11S1 of the semiconductor layer 10. At least a portion of the structure 70 is provided inside the insulating layer 40. Light from a subject to be measured is incident on the structure 70 via the lens section 31. The structure 70 is a fine (minute) structure having a size equal to or less than a predetermined wavelength range of incoming light. The structure 70 has, for example, a size equal to or less than a wavelength range of visible light. The structure 70 may have a size equal to or less than a wavelength range of infrared light.

The structure 70 is, for example, a columnar (pillar-shaped) structure, as illustrated in FIG. 5. The structure 70 is a pillar (columnar member), and is provided on the first surface 11S1 of the semiconductor layer 10. In the example illustrated in FIG. 5, the structure 70 is provided at a middle part of the light-receiving section 12 on the first surface 11S1 of the semiconductor layer 10. The structure 70 can be provided in contact with the light-receiving section 12.

The structure 70 can also be referred to as a protrusion which is a protruding member. The structure 70 is configured integrally with the semiconductor layer 10 (or the light-receiving section 12), and protrudes from the first surface 11S1 of the semiconductor layer 10 toward the light-guiding section 30. The structure 70 is a raised part extending from the first surface 11S1 of the semiconductor layer 10 toward the light-guiding section 30. The structure 70 can also be referred to as a projection that projects toward the filter 35 of the light-guiding section 30. In addition, the structure 70 can also be referred to as a raised pillar (raised columnar part).

In the imaging device 1, one structure 70 is provided for one light-receiving section 12. In the examples illustrated in FIG. 3 to 5 or other drawings, it can be said that one structure 70 is arranged for each transfer transistor 13. The structure 70 is configured using, for example, the same material as that of the light-receiving section 12, and is electrically coupled to the light-receiving section 12. In the example illustrated in FIG. 5, the light-receiving section 12 and the structure 70 are provided integrally.

In the imaging device 1, the structures 70 of the respective pixels P are arranged side by side with a portion of the insulating layer 40 interposed therebetween. In each of the pixels P, the light-blocking section 65 is provided around the structure 70, and is arranged to sandwich the structure 70, for example.

The structure 70 has a refractive index different from a refractive index of an adjacent medium. The structure 70 has a refractive index different from a refractive index of the insulating layer 40 which is a medium around the structure 70. The structure 70 is configured by, for example, a material having a refractive index higher than the refractive index of the surrounding insulating layer 40, and has a refractive index higher than the refractive index of the insulating layer 40. For example, the structure 70 is configured by the same material as that of the light-receiving section 12, and has a refractive index higher than a refractive index of the insulating film of the insulating layer 40.

The structure 70 is configured using the same material as that of the light-receiving section 12, and is configured using, for example, a material such as Si, SiGe, Ge, InGaAs, or InP. The materials of light-receiving section 12 and the structure 70 can be selected depending on a wavelength region of incident light to be measured. For example, in the case of the imaging device 1 that guides visible light, the light-receiving section 12 and the structure 70 may be configured using silicon (Si). In addition, for example, in the case of the imaging device 1 that guides infrared light, the light-receiving section 12 and the structure 70 may be configured using germanium (Ge).

The structure 70 is configured using the same material as that of the light-receiving section 12, and is electrically coupled to the light-receiving section 12. In the example illustrated in FIG. 5, the light-receiving section 12 and the structure 70 are formed continuously and provided integrally. The structure 70 can also be referred to as a portion of the semiconductor layer 10 and the light-receiving section 12. The light-receiving section 12 and the structure 70 can also be collectively referred to as a light-receiving section (or a photoelectric conversion section). The structure 70 is, for example, an n-type semiconductor region or a p-type semiconductor region, and can photoelectrically convert incoming light, together with the light-receiving section 12, to generate an electric signal.

The structure 70 is a light-guiding section, and changes a direction in which incident light travels by a refractive index difference between the structure 70 and the surrounding medium. For example, the structure 70 generates resonance of light of a particular wavelength region depending on the size of the structure 70, thus making it possible to condense light into the structure 70 and in the vicinity thereof.

The size (size), shape, arrangement position, or the like of the structure 70 is defined to allow light of any wavelength region included in the incident light to be condensed on the structure 70 and the light-receiving section 12. The structure 70 is an optical element utilizing a metamaterial (metasurface) technology, and can also be referred to as a light-guiding element that is able to guide light.

Light from a subject is incident on the light-receiving section 12 of each of the pixels P via the lens section 31, the structure 70, and the like. The light-receiving section 12 can receive the light incident via the structure 70 and perform photoelectric conversion to generate electric charge corresponding to a received light amount. Thus, the imaging device 1 uses a pixel signal to be obtained by means of the photoelectric conversion by the light-receiving section 12 to enable generation of a visible image, an infrared image, or the like, for example. It is possible, in the imaging device 1, to cause the structure 70 to appropriately condense the light, thus making it possible to suppress deterioration in sensitivity to incident light. Hereinafter, a description is further given of the imaging device 1 according to the present embodiment in comparison with a comparative example.

FIG. 6 is a diagram illustrating a configuration example of an imaging device according to a comparative example. The comparative example concerns a case where the imaging device 1 includes no structure 70. In the case of the comparative example, as schematically indicated by broken arrows in FIG. 6, light from the lens section 31 may possibly be incident on the light-blocking section 65 and be absorbed, thus de-creasing a received light amount of the light-receiving section 12. In particular, in the case of a fine pixel, the light condensing performance of the lens section 31 is limited by diffraction limitation of the light, thus causing light absorption to tend to easily occur at the light-blocking section 65. In addition, in the case of the comparative example, light is increasingly scattered in the pixel P, thus leading to a possibility that light may leak to surrounding pixels to cause color mixture.

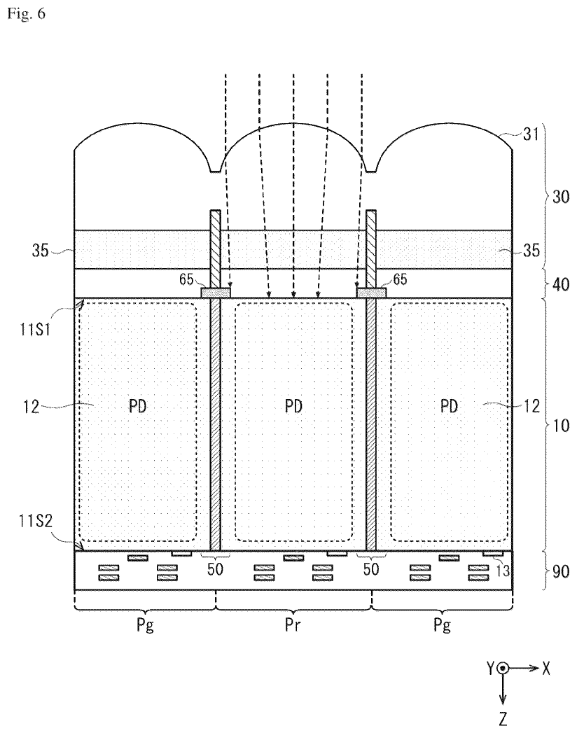

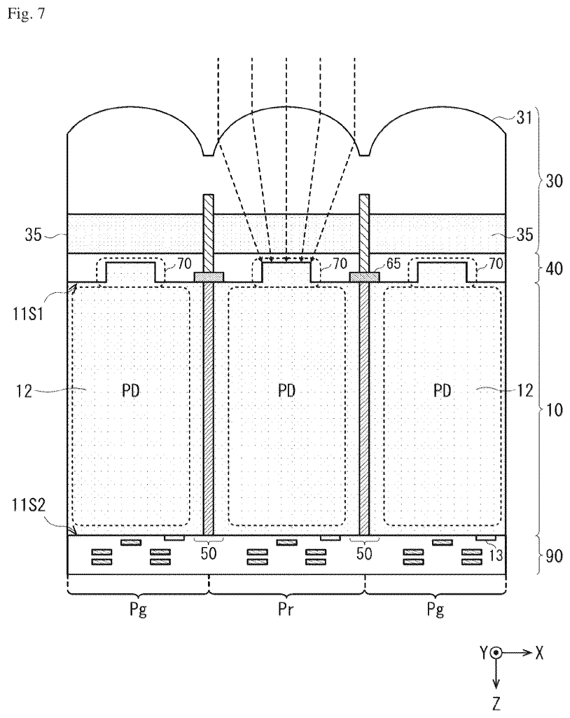

In the present embodiment, the structure 70 is provided on the side of the first surface 11S1 of the semiconductor layer 10, as described above. Therefore, as schematically indicated by broken arrows in FIG. 7, light is able to be condensed in the vicinity of the structure 70, thus making it possible to suppress light absorption at the light-blocking section 65. Light is able to be efficiently condensed on the structure 70 and the light-receiving section 12, thus making it possible to improve quantum efficiency (QE). It is possible to improve sensitivity to incident light.

It is possible, in the imaging device 1 according to the present embodiment, to remarkably improve quantum efficiency in wavelength regions of green (G) and red (R), which are particularly long wavelength regions. Also in the case of the fine pixel, light is able to be appropriately guided to the structure 70 and the light-receiving section 12, thus making it possible to suppress deterioration in sensitivity to incident light.

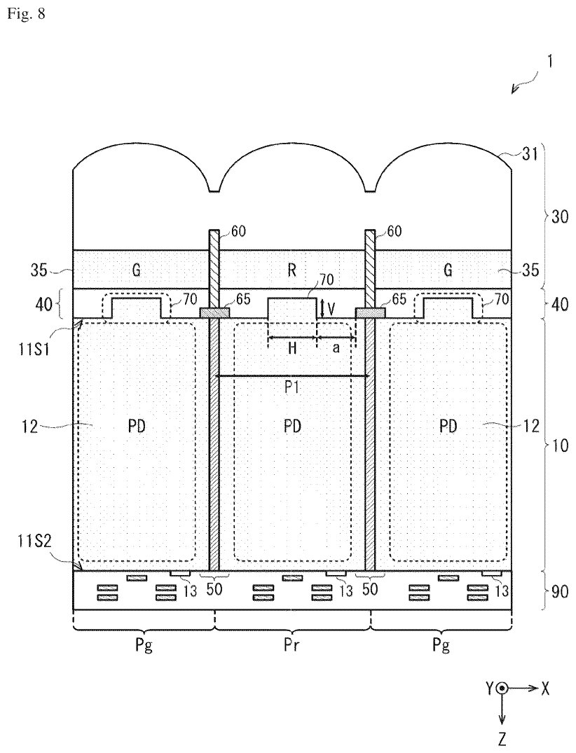

FIG. 8 is a diagram illustrating a configuration example of the imaging device according to the embodiment. As in the example illustrated in FIG. 8, in a direction orthogonal to a stacking direction (Z-axis direction in FIG. 8) of the lens section 31 and the semiconductor layer 10, a width H of the structure 70 may be equal to or less than ½ of a pitch P1 (interval between the pixels P) of the pixel P. In addition, a height V of the structure 70 in the stacking direction of the lens section 31 and the semiconductor layer 10 may be within a range of ±50% of the width H of the structure 70. Configuring the imaging device 1 as described above enables the structure 70 to efficiently condense light, thus making it possible to prevent deterioration in sensitivity to incident light.

In addition, an interval a between the structure 70 and the light-blocking section 65 is, for example, 50 nm or more. In this case, it is possible to suppress incidence of light from the lens section 31 on the light-blocking section 65, and thus to efficiently condense the light on the structure 70 and the light-receiving section 12. It is possible to effectively suppress deterioration in sensitivity to incident light.

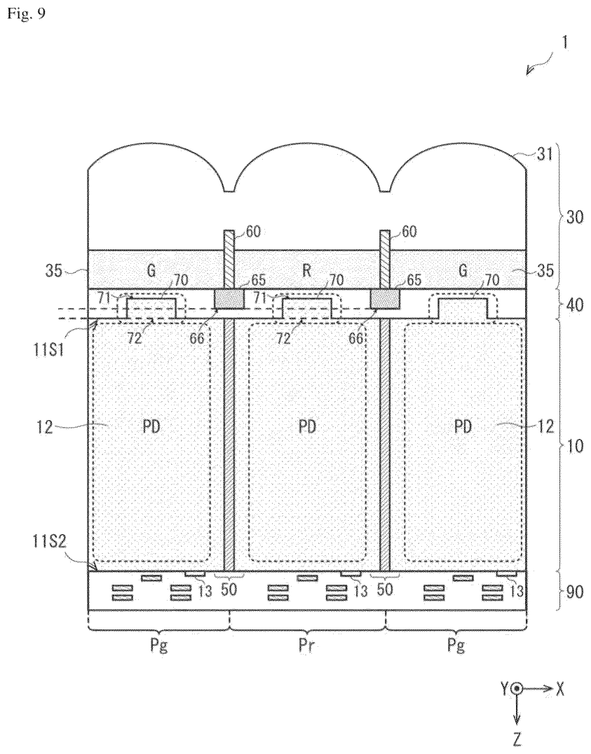

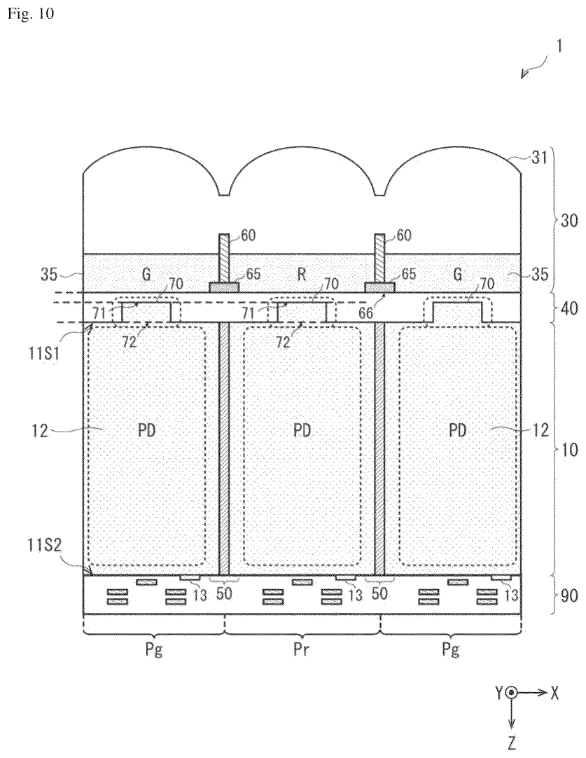

FIGS. 9 and 10 are each a diagram illustrating another configuration example of the imaging device according to the embodiment. As in the example illustrated in FIG. 9 or 10, a bottom 72 of the structure 70 may be positioned closer to the side of the first surface 11S1 of the semiconductor layer 10 than a bottom 66 of the light-blocking section 65. In addition, as in the example illustrated in FIG. 10, an upper part 71 of the structure 70 may be positioned closer to the side of the first surface 11S1 of the semiconductor layer 10 than the bottom 66 of the light-blocking section 65. In the case of the example illustrated in FIG. 9 or 10, it is possible to effectively suppress deterioration in sensitivity to incident light.

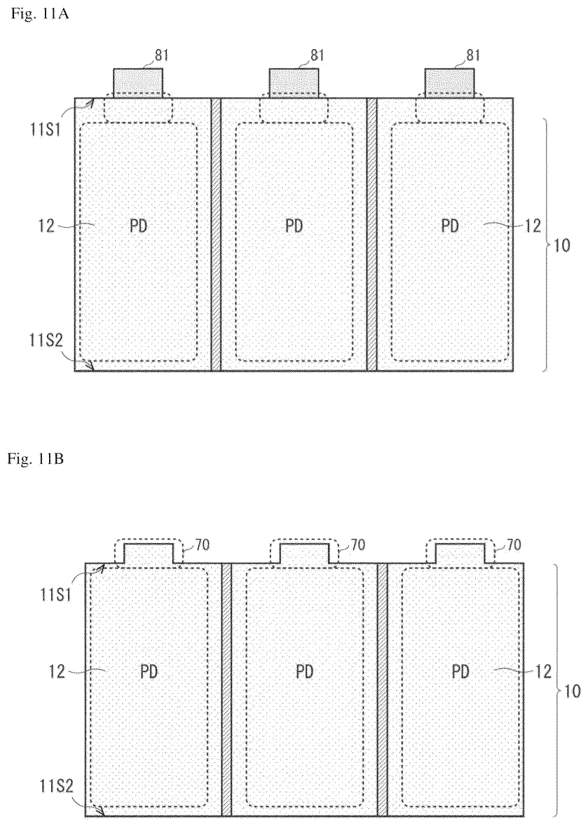

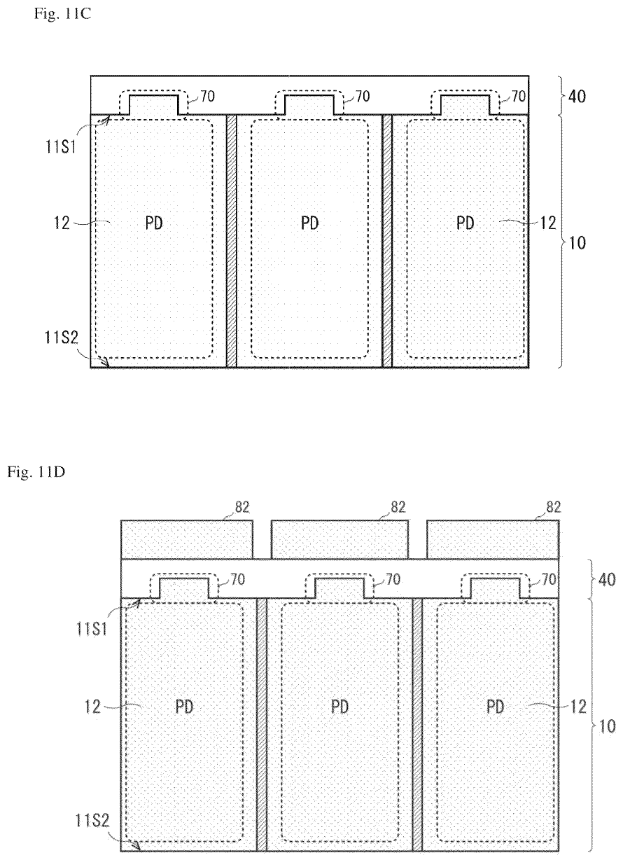

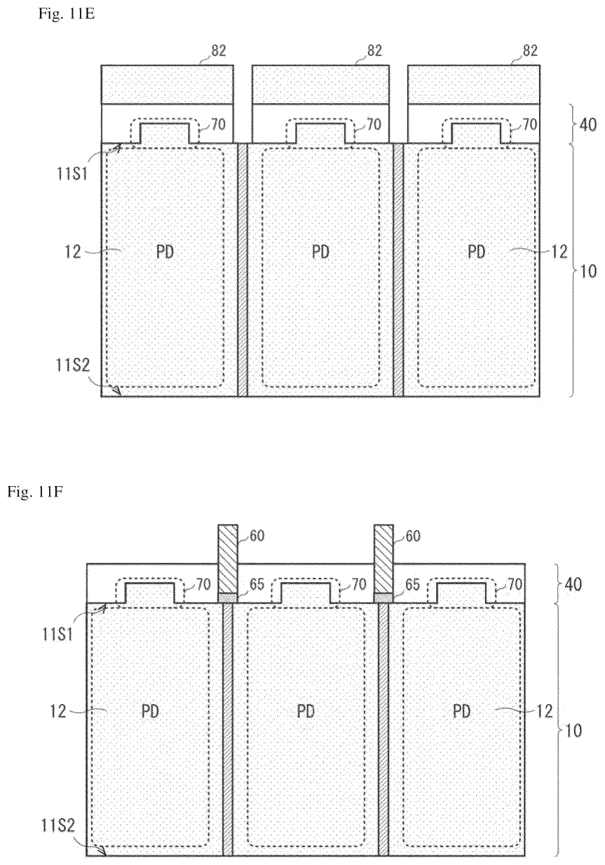

FIG. 11A to 11F are each a diagram illustrating an example of a method of manufacturing the imaging device according to the embodiment. First, as illustrated in FIG. 11A, a resist film 81 is formed, by lithography and etching, on the semiconductor layer 10 in which the light-receiving section 12 is formed. Then, the semiconductor layer 10 is selectively removed by dry-etching, and the structure 70 is formed on the side of the first surface 11S1 of the semiconductor layer 10, as illustrated in FIG. 11B.

Next, a protective film such as a silicon oxide film is formed to cover the structure 70, and thereafter a surface of the protective film is planarized by CMP (Chemical Mechanical Polishing), thereby allowing the insulating layer 40 to be formed, as illustrated in FIG. 11C. Then, as illustrated in FIG. 11D, a resist film 82 is formed on the insulating layer 40 by lithography and etching.

Next, as illustrated in FIG. 11E, the insulating layer 40 is selectively removed by etching. Then, as illustrated in FIG. 11F, the light-blocking section 65 and the light-guiding wall 60 are formed, and thereafter the resist film 82 is removed. Subsequently, the filter 35, the lens section 31, and the like are formed. Through the manufacturing method as described above, the imaging device 1 illustrated in FIG. 5 or other drawings is able to be manufactured. It is to be noted that the above-described manufacturing method is merely exemplary, and another manufacturing method may be employed.

### Workings and Effects

The photodetector according to the present embodiment includes: a first lens (lens section 31); a semiconductor layer (semiconductor layer 10) having a first surface (first surface 11S1) on which light transmitted through the first lens is incident and a second surface (second surface 11S2) on a side opposite to the first surface; a first structure (structure 70) provided on a side of the first surface of the semiconductor layer and having a size equal to or less than a first wavelength range of incident light; and a first light-receiving section (light-receiving section 12) provided between the first surface and the second surface of the semiconductor layer and receiving light incident via the first structure.

The photodetector (imaging device 1) according to the present embodiment is provided with the structure 70 on the side of the first surface 11S1 of the semiconductor layer 10. This makes it possible to efficiently condense incoming light on the structure 70 and the light-receiving section 12. It is possible to implement a photodetector that makes it possible to efficiently condense light.

Next, descriptions are given of modification examples of the present disclosure. Hereinafter, components similar to those of the foregoing embodiment are denoted by the same reference numerals, and descriptions thereof are omitted as appropriate.

### 2. Modification Examples

### 2-1. Modification Example 1

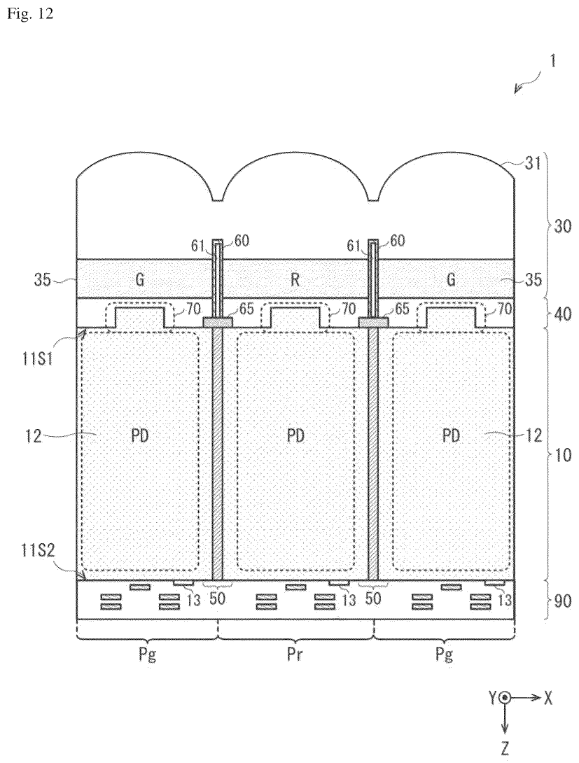

FIG. 12 is a diagram illustrating an example of a cross-sectional configuration of an imaging device according to Modification Example 1 of the present disclosure. The light-guiding wall 60 may be configured using air (air gap). In the example illustrated in FIG. 12, the light-guiding wall 60 has an air gap 61 (cavity). Providing the air gap 61 inside the light-guiding wall 60 suppresses light leakage into surrounding pixels, thus making it possible to effectively suppress occurrence of color mixture.

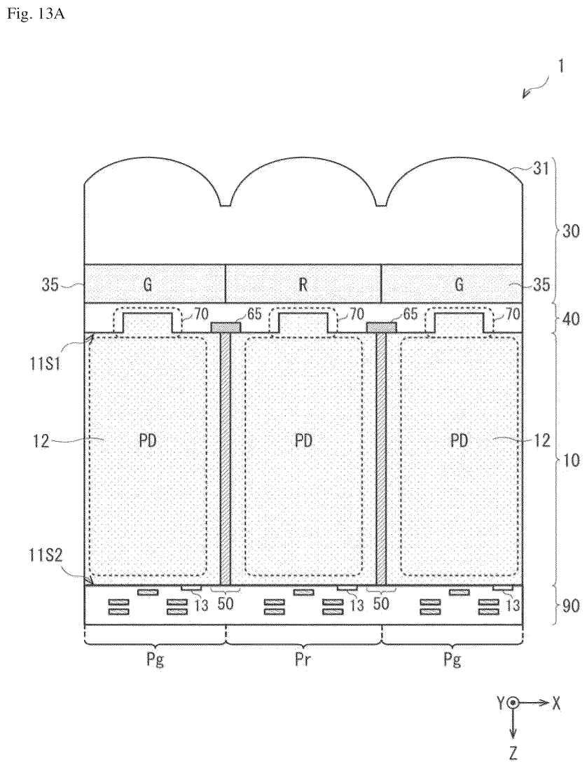

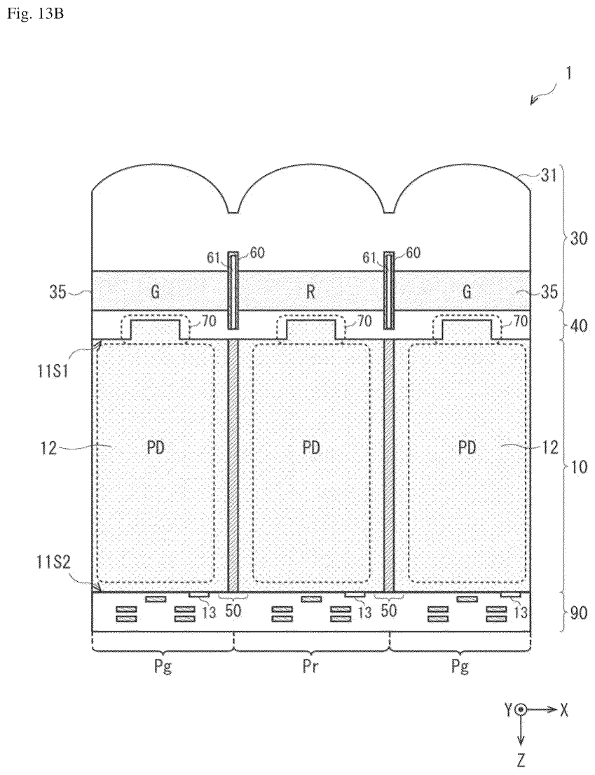

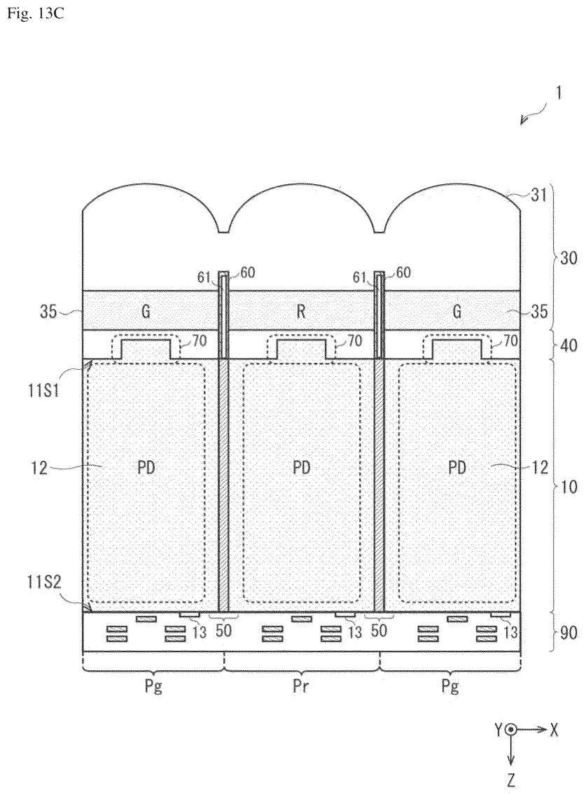

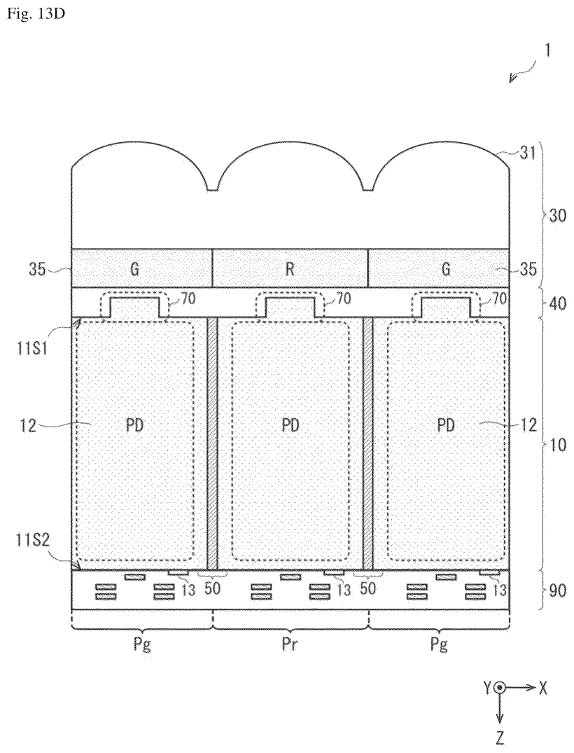

FIGS. 13A to 13D are each a diagram illustrating another example of the cross-sectional configuration of the imaging device according to Modification Example 1. As in the example illustrated in FIG. 13A, the light-guiding wall 60 may not be arranged in each of the pixels P of the imaging device 1. For example, in a case where sufficient light-condensing performance is obtained by the structure 70, the light-guiding wall 60 may not be provided, as in the example illustrated in FIG. 13A. In this case, as compared with the case of forming the light-guiding wall 60, it is possible to reduce the manufacturing costs of the imaging device 1. In addition, an improvement in mechanical resistance is expectable.

It is to be noted that, as in the example illustrated in FIG. 13B or 13C, the light-blocking section 65 (light-blocking film) may not be arranged in each of the pixels P of the imaging device 1. For example, depending on the characteristics of the structure 70, the light-blocking section 65 may not be provided in some or all of the pixels P of the imaging device 1. In addition, as in the example illustrated in FIG. 13D, the imaging device 1 may not be provided with the light-guiding wall 60 and the light-blocking section 65. It is possible to reduce the manufacturing costs of the imaging device 1.

### 2-2. Modification Example 2

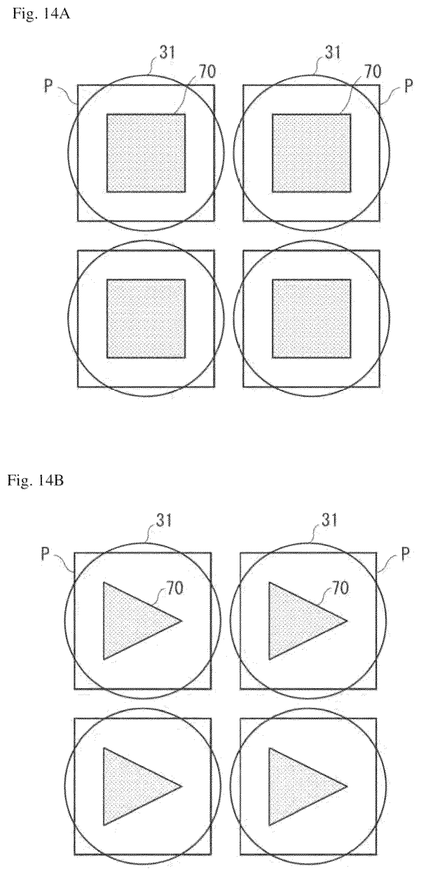

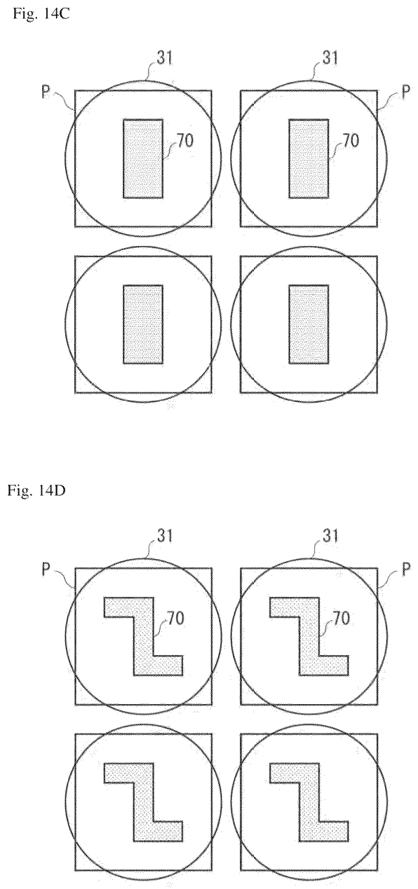

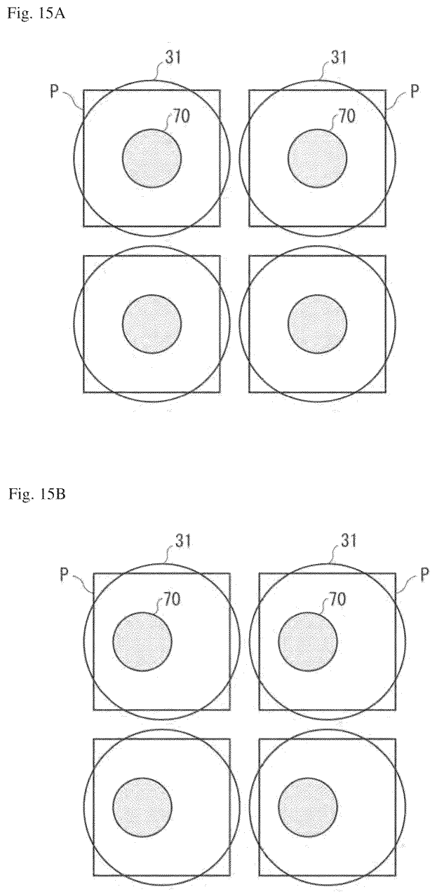

FIGS. 14A to 14D are each a diagram illustrating an example of a planar configuration of an imaging device according to Modification Example 2. The shape of the structure 70 is appropriately modifiable, and may be, for example, a quadrangular shape in a plan view, as illustrated in FIG. 14A. The shape of the structure 70 may be a rectangular parallelepiped or a cube.

The structure 70 may have a horizontally asymmetric shape or a vertically asymmetric shape, such as a triangle illustrated in FIG. 14B, or a rectangle illustrated in FIG. 14C. Arranging the structure 70 having such a shape makes it possible to suppress deterioration in sensitivity to oblique incident light. In addition, adjusting the shape of the structure 70 depending on an image height makes it possible to appropriately perform pupil correction.

The shape of the structure 70 may be a shape having chirality, as in the example illustrated in FIG. 14D. In this case, in the imaging device 1, a difference is generated between sensitivity to clockwise circularly polarized light and sensitivity to counter-clockwise circularly polarized light, thus making it possible to detect an orientation of the circularly polarized light.

### 2-3. Modification Example 3

FIGS. 15A and 15B are each a diagram illustrating an example of a cross-sectional configuration of an imaging device according to Modification Example 3. In the imaging device 1, positions of the structures 70 in the respective pixels P may be configured to differ depending on a distance from the center of the pixel section 100 (pixel array), i.e., an image height.

In a peripheral part positioned outside the middle part of the pixel section 100, i.e., in a region distant from the middle of the pixel section 100, the structure 70 is provided to be shifted from the center of the pixel P (e.g., the center position of the lens section 31, the center position of the light-receiving section 12, etc.) to correspond to an incident direction of light from a subject, for example, as illustrated in FIG. 15B. In the middle region of the pixel section 100, the pixel P is configured as illustrated in FIG. 15A, for example. The positions of the structures 70 are adjusted depending on the image height, thus making it possible to perform pupil correction.

### 2-4. Modification Example 4

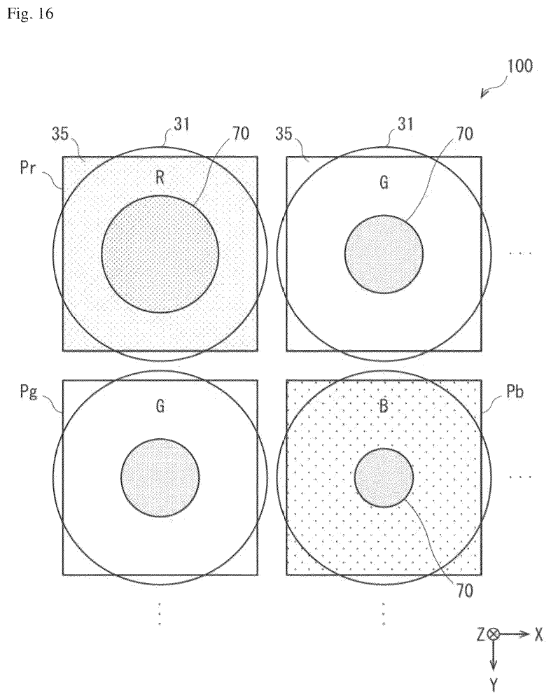

FIG. 16 is a diagram illustrating an example of a cross-sectional configuration of an imaging device according to Modification Example 4. The pixels P of respective colors may include the structures 70 having different sizes. The size of the structure 70 may be set depending on a wavelength of light to be detected in the pixel P of each of the colors. For example, the structure 70 of the pixel Pr has a size equal to or less than a red wavelength range, and the structure 70 of the pixel Pg has a size equal to or less than a green wavelength range. In addition, the structure 70 of the pixel Pb has a size equal to or less than a blue wavelength range.

In the example illustrated in FIG. 16, the size of the structure 70 of the pixel Pr is larger than the size of the structure 70 of the pixel Pg. In addition, the size of the structure 70 of the pixel Pg is larger than the size of the structure 70 of the pixel Pb. By changing the size of the structure 70 for each of the pixels P of the respective colors to correspond to a wavelength region of light to be detected, it is possible to improve quantum efficiency in each of the pixels P of the respective colors. It is possible to improve sensitivity of each pixel P of the respective colors. In addition, it is possible to effectively suppress color mixture between the pixels P.

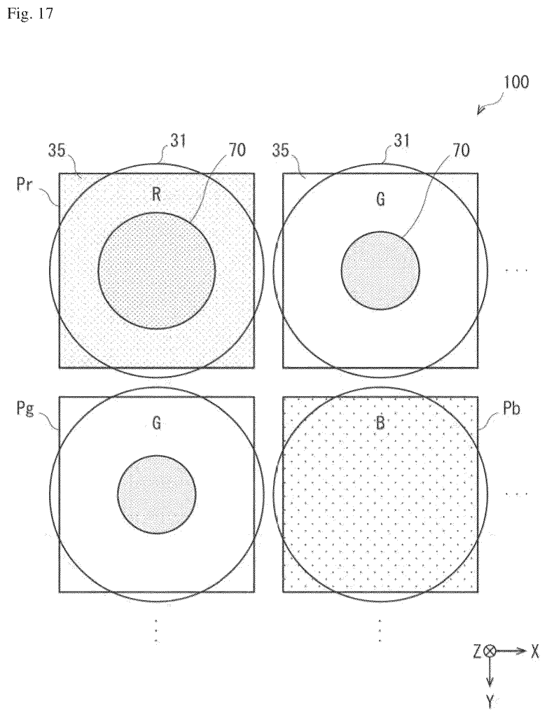

It is to be noted that not all the pixels P of the imaging device 1 need to include the structure 70; some of the pixel P may not be provided with the structure 70. For example, in a case where an amount of improvement in quantum efficiency in a blue (B) wavelength region is relatively small, the structure 70 may not be arranged in the pixel Pb, as in the example illustrated in FIG. 17. In the example illustrated in FIG. 17, the structure 70 is provided in the pixel Pg and the pixel Pr. In addition, for example, the structure 70 may be arranged only in one of the pixel Pg or the pixel Pr.

### 2-5. Modification Example 5

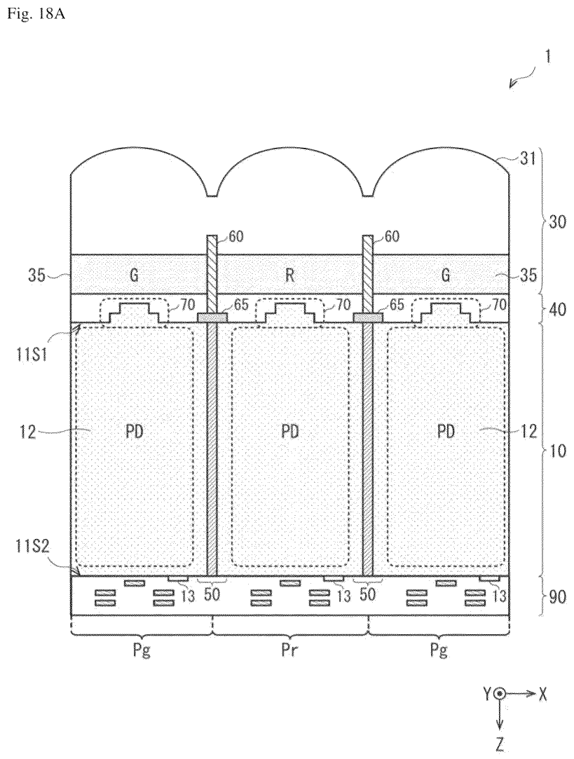

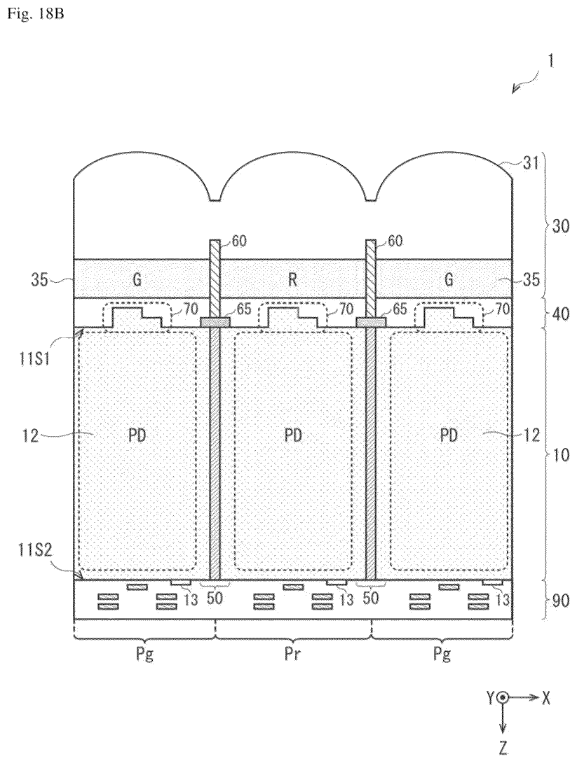

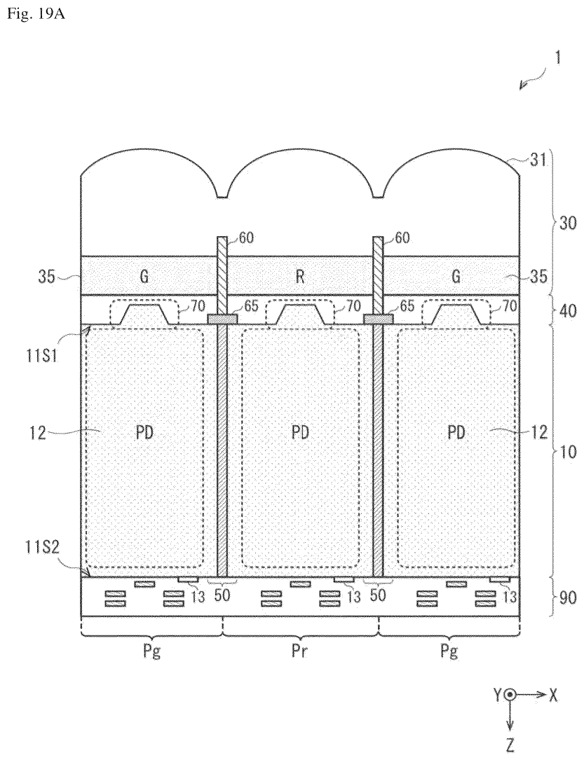

FIGS. 18A and 18B are each a diagram illustrating an example of a cross-sectional configuration of an imaging device according to Modification Example 5. As in the example illustrated in FIG. 18A or 18B, the structure 70 may have a multi-stage shape. The structure 70 can also be referred to as having a stepped shape. With such a configuration, it is possible to reduce (suppress) reflection at an interface of the semiconductor layer 10, and thus to improve sensitivity to incident light. In addition, it is possible to improve sensitivity to oblique incident light.

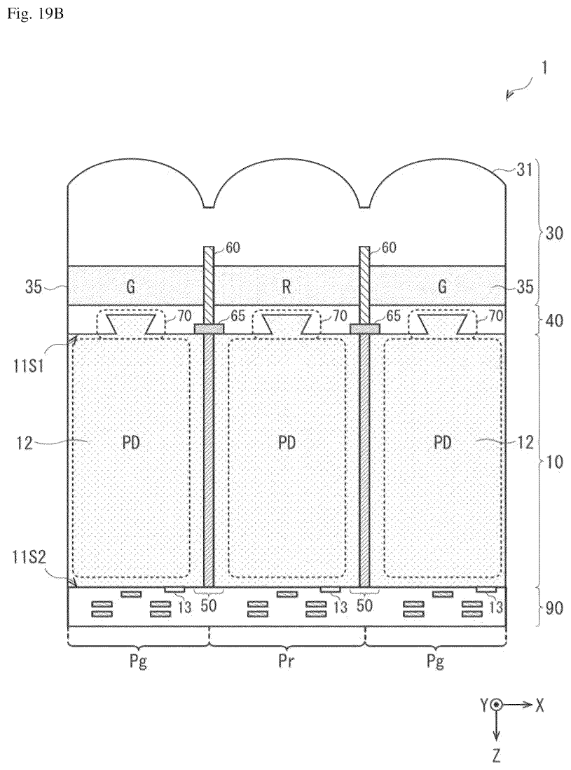

FIGS. 19A and 19B are each a diagram illustrating another example of the cross-sectional configuration of the imaging device according to Modification Example 5. As in the example illustrated in FIG. 19A or 19B, the structure 70 may have a tapered shape (a shape with an inclined part). This tapered shape is able to be formed by lithography and etching.

In the example illustrated in FIG. 19A or 19B, the cross-sectional shape of a top surface of the structure 70 and the cross-sectional shape of an undersurface (bottom surface) of the structure 70 differ from each other. Allowing the structure 70 to have a tapered shape makes it possible to suppress a rapid change in the refractive index. It is possible to adjust a reflectance at the structure 70, and thus to improve sensitivity to incident light.

### 2-6. Modification Example 6

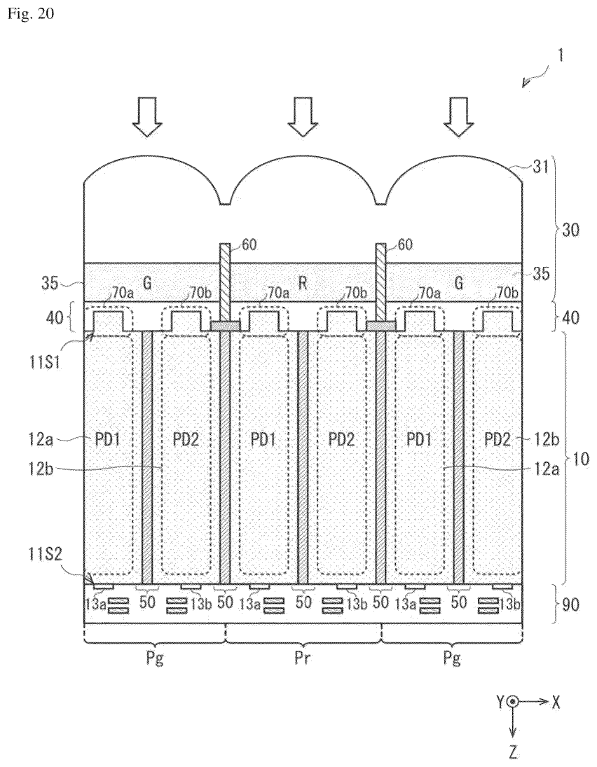

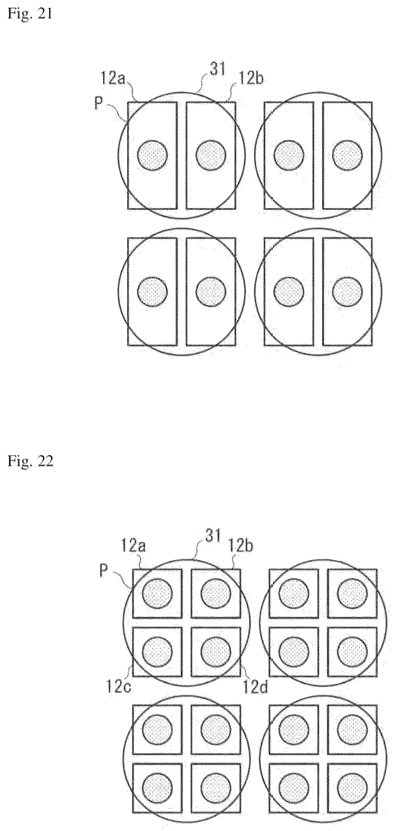

FIG. 20 is a diagram illustrating an example of a cross-sectional configuration of an imaging device according to Modification Example 6. FIG. 21 is a diagram illustrating an example of a planar configuration of the imaging device according to Modification Example 6. In the imaging device 1, according to the present modification example, each of the pixels P includes a light-receiving section 12a and a light-receiving section 12b, as illustrated in FIGS. 20 and 21. A transfer transistor 13a is provided for the light-receiving section 12a, and a transfer transistor 13b is provided for the light-receiving section 12b. It is to be noted that FIG. 20 schematically illustrates gate electrodes of the respective transfer transistors 13a and 13b. The light-receiving section 12a and the light-receiving section 12b are configured by, for example, photodiodes PD1 and PD2, respectively.

One lens section 31 is provided for the light-receiving section 12a and the light-receiving section 12b of the pixel P. The light-receiving section 12a and the light-receiving section 12b receive light beams having passed through different regions of an optical system such as an imaging lens or the like to perform pupil division. Therefore, using a first pixel signal based on electric charge photoelectrically converted by the light-receiving section 12a and a second pixel signal based on electric charge photo-electrically converted by the light-receiving section 12b makes it possible to obtain phase difference data (phase difference information). Using the phase difference data makes it possible to perform phase difference AF (Auto Focus).

In the present modification example, a structure 70a is provided for the light-receiving section 12a, and a structure 70b is provided for the light-receiving section 12b. This enables the pupil division to be appropriately performed, thus making it possible to suppress deterioration of accuracy in detection of a phase difference.

Suppose a case where there is no structure 70, it is conceivable that color mixture and deterioration in sensitivity may occur due to reflection/scattering at the separation section 50 as well as absorption at the light-blocking section 65. In contrast, in the imaging device 1 according to the present modification example, providing the structure 70a and the structure 70b makes it possible to improve sensitivities of the light-receiving section 12a and the light-receiving section 12b while suppressing color mixture. It is therefore possible to improve the accuracy in detection of a phase difference.

It is to be noted that, although the description has been given of the example in which each of the pixels P includes the two light-receiving sections 12 (light-receiving sections 12a and 12b in FIG. 20), the number and the arrangement of the light-receiving sections 12 are not limited thereto. For example, as in the example illustrated in FIG. 22, the imaging device 1 may include four light-receiving sections 12 (light-receiving sections 12a to 12d in FIG. 22) for each of the pixels P. In addition, each of the pixels P may include four or more light-receiving sections 12.

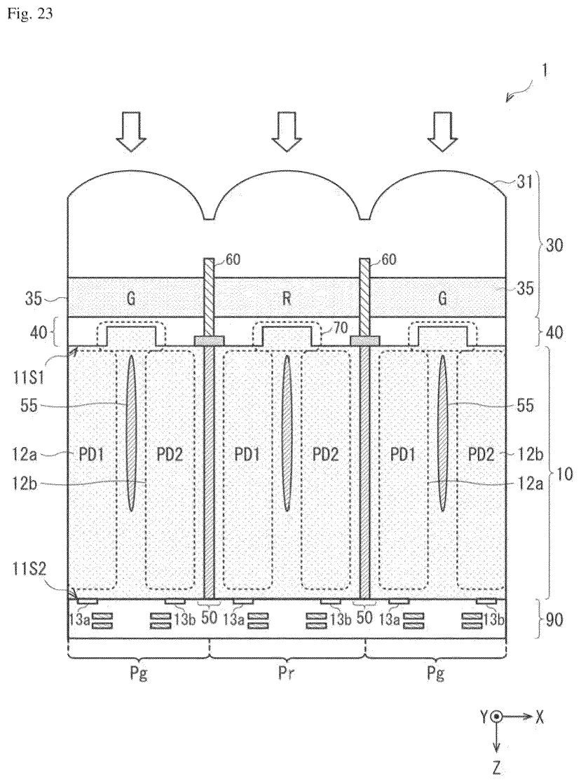

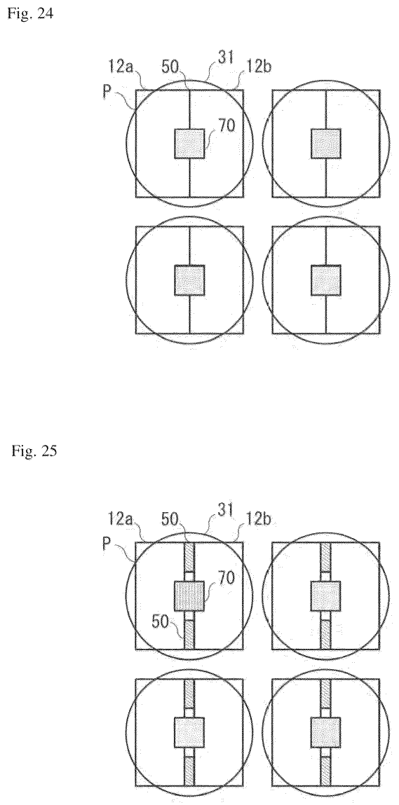

FIGS. 23 and 24 are each a diagram illustrating another configuration example of the imaging device according to Modification Example 6. As in the example illustrated in FIG. 23, a separation section 55 that forms a potential barrier may be arranged between the light-receiving section 12a and the light-receiving section 12b adjacent to each other to electrically separate the light-receiving section 12a and the light-receiving section 12b from each other. The separation section 55 is, for example, a p-type semiconductor region formed by ion implantation. It is to be noted that the separation section 55 may be configured by an n-type semiconductor region.

As illustrated in FIG. 23, one structure 70 may be arranged for the light-receiving section 12a and the light-receiving section 12b. As compared with the case where the structure 70 is provided individually for each of the light-receiving section 12a and the light-receiving section 12b, the size of the structure 70 is larger, thus making it possible to relax required accuracy in processing the structure 70. In addition, it is possible to distance a light-condensing spot by the structure 70 from surrounding pixels P, thus making it possible to reduce color mixture between the pixels P. It is to be noted that, as in the example illustrated in FIG. 25, the separation section 50 that penetrates the semiconductor layer 10 may be arranged in a portion of a region between the light-receiving section 12a and the light-receiving section 12b adjacent to each other.

### 2-7. Modification Example 7

The description has been given, in the foregoing embodiment, of the configuration examples of the pixel P and the light-receiving section 12, but the configurations of the pixel P and the light-receiving section 12 are not limited to the above-described examples. For example, the technology according to the present disclosure is applicable to a device using SPAD (Single Photon Avalanche Diode).

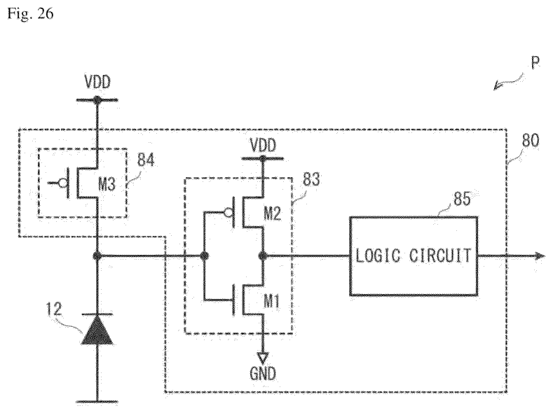

FIG. 26 is a diagram illustrating a configuration example of a pixel of a photodetector according to Modification Example 7. The pixel P has the light-receiving section 12 (light-receiving element) and a readout circuit 80. The light-receiving section 12 is configured to receive light and generate a signal. The light-receiving section 12 is an SPAD element, and includes a multiplication region (multiplication part) that enables avalanche multiplication. The light-receiving section 12 can convert incoming photon into electric charge to output an electric signal in response to the incident photon. The light-receiving section 12 can also be referred to as a photoelectric conversion element (photoelectric conversion section) configured to be able to photoelectrically convert light.

The readout circuit 80 includes circuits to read a signal based on a photocurrent flowing through the light-receiving section 12, e.g., a generation section 83, a supply section 84, a logic circuit 85, and the like. The generation section 83 is configured by an inverter, for example. The logic circuit 85 is configured by a counter circuit, a TDC (Time to Digital Converter) circuit, or the like.

The supply section 84 is configured to be able to supply the light-receiving section 12 with a voltage and a current. The supply section 84 can supply the light-receiving section 12 with a current, for example, in a case where avalanche multiplication occurs and a potential differential between electrodes of the light-receiving section 12 is smaller than a breakdown voltage. The supply section 84 recharges the light-receiving section 12 to bring the light-receiving section 12 back into a state enabling an operation in a Geiger mode. The supply section 84 is a recharging section, and can also be referred to as recharging the light-receiving section 12 with electric charge and recharging the light-receiving section 12 with a voltage. In addition, the supply section 84 is also referred to as a quench section (quench circuit). The readout circuit 80 is configured to be able to output a signal based on a current of the light-receiving section 12.

As an example, in a case where a measurement target is irradiated with light (e.g., laser light) by a light source (unillustrated), the photodetector receives light reflected by the measurement target. Each of the pixels P of the photodetector receives the light reflected by the measurement object to generate a signal in response to incidence of a photon (photon). The signal of the pixel P serves as a signal corresponding to a distance to the measurement target, and is read by the readout circuit 80. The photodetector is able to acquire a distance image by using signals of the respective pixels P.

In a case where the structure 70 is applied to the pixel P in which the SPAD element is used as the light-receiving section 12, it is possible to appropriately guide light to the light-receiving section 12 (SPAD element), and thus to improve sensitivity to incident light. For example, in the case of a distance measuring device that is able to execute distance measurement, it is possible to improve accuracy in the distance measurement.

### 3. Application Example

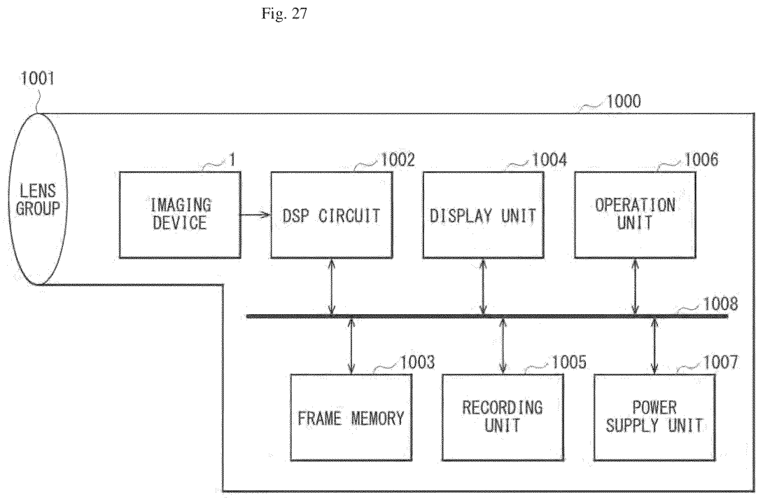

The above-described imaging device 1 or the like is applicable, for example, to any type of electronic apparatus with an imaging function including a camera system such as a digital still camera or a video camera, a mobile phone having an imaging function, and the like. FIG. 27 illustrates a schematic configuration of an electronic apparatus 1000.

The electronic apparatus 1000 includes, for example, a lens group 1001, the imaging device 1, a DSP (Digital Signal Processor) circuit 1002, a frame memory 1003, a display unit 1004, a recording unit 1005, an operation unit 1006, and a power supply unit 1007. They are coupled to each other via a bus line 1008.

The lens group 1001 takes in incident light (image light) from a subject, and forms an image on an imaging surface of the imaging device 1. The imaging device 1 converts the amount of incident light formed as an image on the imaging surface by the lens group 1001 into electric signals on a pixel-by-pixel basis, and supplies the DSP circuit 1002 with the electric signals as pixel signals.

The DSP circuit 1002 is a signal processing circuit that processes signals supplied from the imaging device 1. The DSP circuit 1002 outputs image data obtained by processing the signals from the imaging device 1. The frame memory 1003 temporarily holds the image data processed by the DSP circuit 1002 on a frame-by-frame basis.

The display unit 1004 includes, for example, a panel-type display device such as a liquid crystal panel or an organic EL (Electro Luminescence) panel, and records image data of a moving image or a still image captured by the imaging device 1 in a recording medium such as a semiconductor memory or a hard disk.

The operation unit 1006 outputs an operation signal for a variety of functions of the electronic apparatus 1000 in accordance with an operation by a user. The power supply unit 1007 appropriately supplies the DSP circuit 1002, the frame memory 1003, the display unit 1004, the recording unit 1005, and the operation unit 1006 with various kinds of power for operations of these supply targets.

### 4. Practical Application Examples

### (Example of Practical Application to Mobile Body)

The technology (the present technology) according to the present disclosure is applicable to a variety of products. For example, the technology according to the present disclosure may be achieved as a device mounted on any type of mobile body such as an automobile, an electric vehicle, a hybrid electric vehicle, a motorcycle, a bicycle, a personal mobility, an aircraft, a drone, a vessel, or a robot.

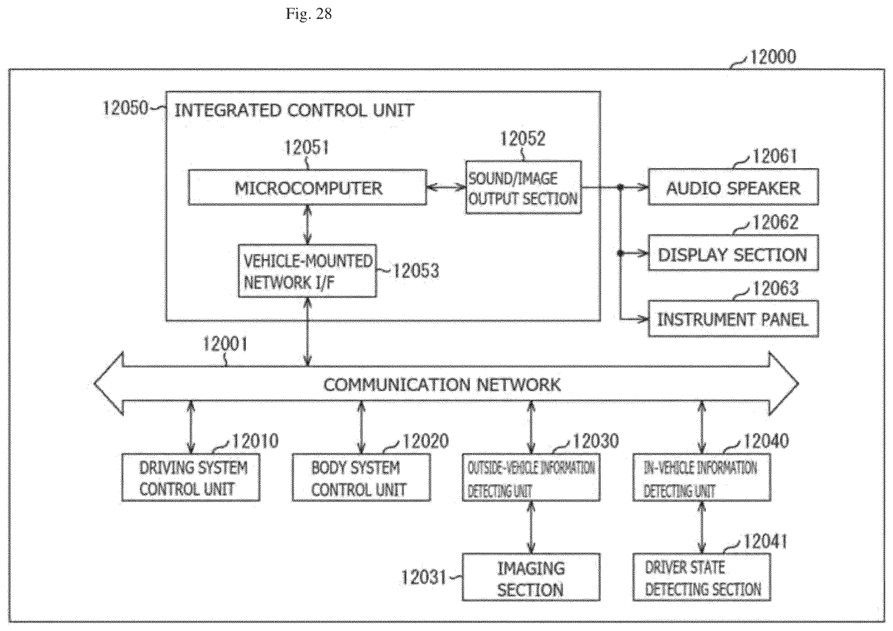

FIG. 28 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 28, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 28, an audio speaker 12061, a display section 12062, and an instrument panel 12063 are illustrated as the output device. The display section 12062 may, for example, include at least one of an on-board display and a head-up display.

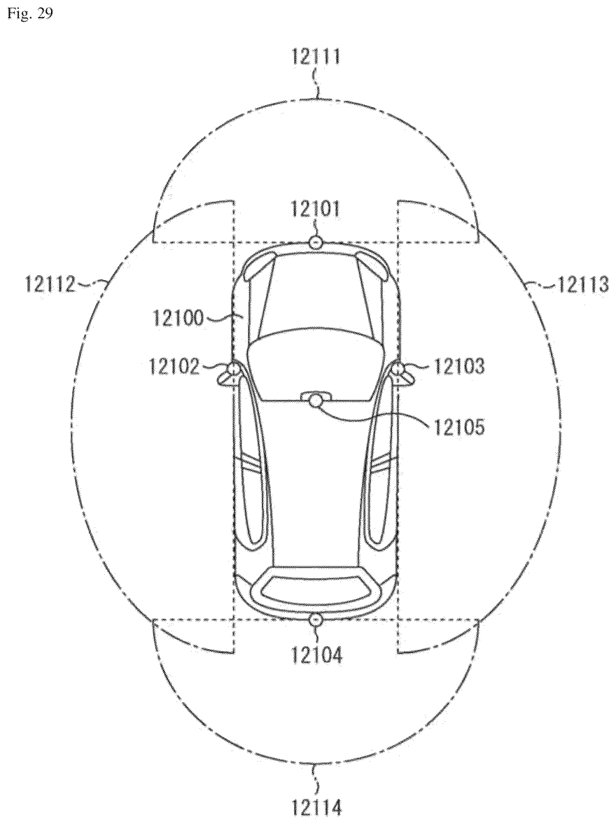

FIG. 29 is a diagram depicting an example of the installation position of the imaging section 12031.

In FIG. 29, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 29 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by super-imposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of the mobile body control system to which the technology according to an embodiment of the present disclosure is applicable. The technology according to an embodiment of the present disclosure is applicable to the imaging section 12031, for example, of the configurations described above. Specifically, for example, the imaging device 1 or the like can be applied to the imaging section 12031. Applying the technology according to an embodiment of the present disclosure to the imaging section 12031 enables obtainment of a photographed image having high definition, thus making it possible to perform highly accurate control utilizing the photographed image in the mobile body control system.

### (Example of Practical Application to Endoscopic Surgery System)

The technology according to an embodiment of the present disclosure (present technology) is applicable to various products. For example, the technology according to an embodiment of the present disclosure may be applied to an endoscopic surgery system.

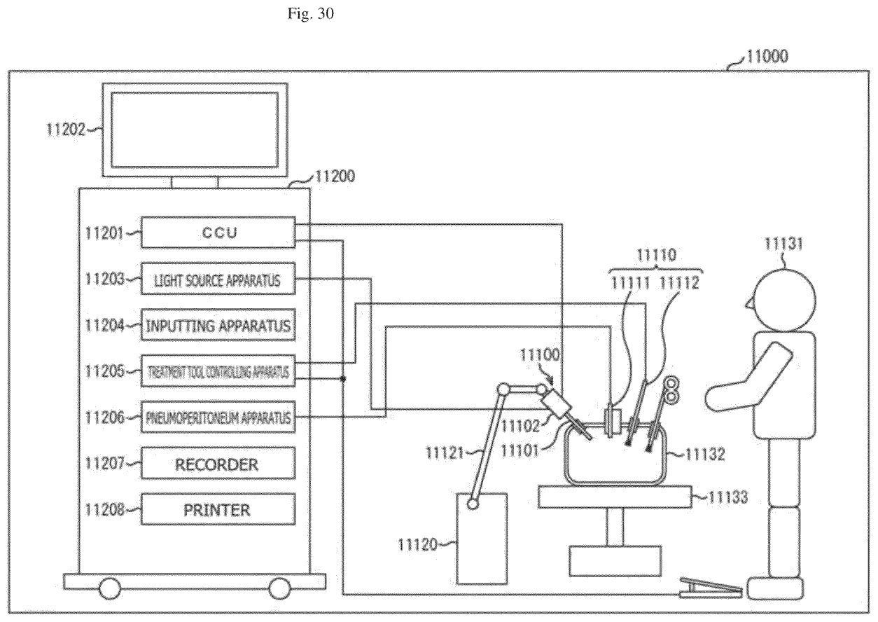

FIG. 30 is a view depicting an example of a schematic configuration of an endoscopic surgery system to which the technology according to an embodiment of the present disclosure (present technology) can be applied.

In FIG. 30, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be output is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/ or excitation light suitable for special light observation as described above.

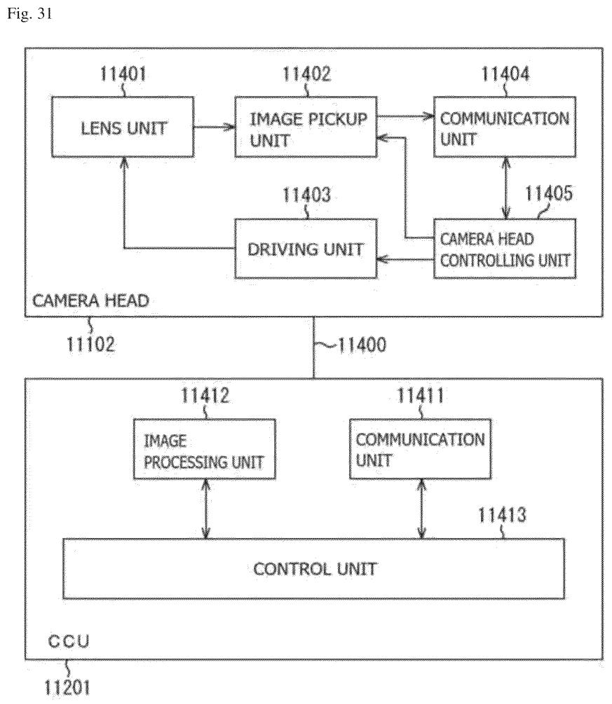

FIG. 31 is a block diagram depicting an example of a functional configuration of the camera head 11102 and the CCU 11201 depicted in FIG. 30.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given hereinabove of one example of the endoscopic surgery system, to which the technology according to an embodiment of the present disclosure is applicable. The technology according to an embodiment of the present disclosure is suitably applicable to, for example, the image pickup unit 11402 provided in the camera head 11102 of the endoscope 11100 of the configurations described above. Applying the technology according to an embodiment of the present disclosure to the image pickup unit 11402 enables the image pickup unit 11402 to have high sensitivity, thus making it possible to provide the endoscope 11100 having high definition.

Although the description has been given hereinabove of the present disclosure with reference to the embodiment, the modification examples, the application example, and the practical application examples, the present technology is not limited to the foregoing embodiment and the like, and may be modified in a wide variety of ways. For example, although the foregoing modification examples have been described as modification examples of the foregoing embodiment, the configurations of the respective modification examples may be combined as appropriate. For example, the present disclosure is not limited to a back-illuminated image sensor, and is also applicable to a front-illuminated image sensor.

The photodetector according to an embodiment of the present disclosure includes: a first lens; a semiconductor layer having a first surface on which light transmitted through the first lens is incident and a second surface on a side opposite to the first surface; a first structure provided on a side of the first surface of the semiconductor layer and having a size equal to or less than a first wavelength range of incident light; and a first light-receiving section provided between the first surface and the second surface of the semiconductor layer and receiving light incident via the first structure. It is therefore possible to efficiently condense incoming light on the first structure and the first light-receiving section. It is possible to implement a photodetector that makes it possible to efficiently condense light.

It is to be noted that the effects described herein are merely exemplary and are not limited to the description, and may further include other effects. In addition, the present disclosure may also have the following configurations.

It should be understood by those skilled in the art that various modifications, combinations, sub-combinations and alterations may occur depending on design requirements and other factors insofar as they are within the scope of the appended claims or the equivalents thereof.
(1) An imaging device comprising:
   a semiconductor layer including a plurality of light-receiving sections, wherein a color filter is disposed above each of the plurality of light-receiving sections;
   a plurality of light-guiding walls provided between color filters; and
   a plurality of structures configured to guide incident light to the plurality of light-receiving sections, wherein the plurality of structures are provided on a light incident side of the semiconductor layer.
(2) The imaging device according to (1), further comprising:
   a plurality of light-blocking sections provided as a bottom of each light guiding wall.
(3)The imaging device according to any of (1) or (2), wherein each of the plurality of light-guiding walls is taller than the color filters in a cross-sectional view.
(4) The imaging device according to any one of (1) to (3), wherein the separation section has a trench provided at a boundary between adjacent light-receiving sections.
(5) The imaging device according to (4), wherein the separation section including the trench can be provided to penetrate the semiconductor layer.
(6) The imaging device according to any one of (4) to (5), wherein an insulating film is provided inside the trench of the separation section.
(7) The imaging device according to any one of (4) to (6), wherein a cavity may be provided inside the trench of the separation section.
(8) The imaging device according to any one of (1) to (7), wherein the plurality of light-guiding walls have a refractive index lower than a refractive index of a surrounding medium.
(9) The imaging device according to any one of (1) to (8), wherein at least a portion of the structure is provided inside an insulating layer disposed above the semiconductor layer.
(10) The imaging device according to any one of (1) to (9), wherein the structure has a size equal to or less than a predetermined wavelength range of incoming light.
(11) The imaging device according to any one of (1) to (10), wherein the structure is a size equal to or less than a wavelength range of visible light.
(12) The imaging device according to any one of (1) to (11), wherein the structure has a size equal to or less than a wavelength range of infrared light.
(13) The imaging device according to any one of (1) to (12), wherein a radius of the plurality of structures vary based on a color of an associated color filter.
(14) The imaging device according to any one of (1) to (13), wherein a cross-section of the plurality of structures have a square shape or rectangular shape.
(15) The imaging device according to any one of (1) to (14), wherein a cross-section of the plurality of structures have a triangle shape.
(16) The imaging device according to any one of (1) to (15), wherein the structure is arranged for each transfer transistor.
(17) The imaging device according to any one of (1) to (16), wherein the structure has a refractive index different from a refractive index of the surrounding insulating layer.
(18) An electronic apparatus comprising an imaging device, the imaging device including:
   a semiconductor layer including a plurality of light-receiving sections, wherein a color filter is disposed above each of the plurality of light-receiving sections;
   a plurality of light-guiding walls provided between color filters; and
   a plurality of structures configured to guide incident light to the plurality of light-receiving sections, wherein the plurality of structures are provided on a light incident side of the semiconductor layer; and
   a processing circuit that processes a generated image signal.
(19) The electronic apparatus according to (18), wherein each of the plurality of light-guiding walls is taller than the color filters in a cross-sectional view.
(20) The electronic apparatus according to any one of (18) or (19), wherein a cross-section of the plurality of structures have a rectangular or triangular shape.

### REFERENCE SIGNS LIST

1 imaging device
10 semiconductor layer
12 light-receiving section
31 lens section
35 filter
40 insulating layer
50 separation section
60 light-guiding wall
65 light-blocking section
70 structure
100 pixel section

What is claimed is:

1. An imaging device, comprising:
a semiconductor layer including a plurality of light-receiving sections, wherein a color filter is disposed above each of the plurality of light-receiving sections;
a plurality of light-guiding walls provided between color filters; and
a plurality of structures configured to guide incident light to the plurality of light-receiving sections, wherein the plurality of structures are provided on a light incident side of the semiconductor layer.

2. The imaging device according to claim 1, further comprising:
a plurality of light-blocking sections provided as a bottom of each light guiding wall.

3. The imaging device according to claim 1, wherein each of the plurality of light-guiding walls is taller than the color filters in a cross-sectional view.

4. The imaging device according to claim 1, wherein the separation section has a trench provided at a boundary between adjacent light-receiving sections.

5. The imaging device according to claim 4, wherein the separation section including the trench can be provided to penetrate the semiconductor layer.

6. The imaging device according to claim 4, wherein an insulating film is provided inside the trench of the separation section.

7. The imaging device according to claim 4, wherein a cavity may be provided inside the trench of the separation section.

8. The imaging device according to claim 1, wherein the plurality of light-guiding walls have a refractive index lower than a refractive index of a surrounding medium.

9. The imaging device according to claim 1, wherein at least a portion of the structure is provided inside an insulating layer disposed above the semiconductor layer.

10. The imaging device according to claim 1, wherein the structure has a size equal to or less than a predetermined wavelength range of incoming light.

11. The imaging device according to claim 1, wherein the structure is a size equal to or less than a wavelength range of visible light.

12. The imaging device according to claim 1, wherein the structure has a size equal to or less than a wavelength range of infrared light.

13. The imaging device according to claim 1, wherein a radius of the plurality of structures vary based on a color of an associated color filter.

14. The imaging device according to claim 1, wherein a cross-section of the plurality of structures have a square shape or rectangular shape.

15. The imaging device according to claim 1, wherein a cross-section of the plurality of structures have a triangle shape.

16. The imaging device according to claim 1, wherein the structure is arranged for each transfer transistor.

17. The imaging device according to claim 1, wherein the structure has a refractive index different from a refractive index of the surrounding insulating layer.

18. An electronic apparatus comprising an imaging device, the imaging device including:
a semiconductor layer including a plurality of light-receiving sections, wherein a color filter is disposed above each of the plurality of light-receiving sections;
a plurality of light-guiding walls provided between color filters; and
a plurality of structures configured to guide incident light to the plurality of light-receiving sections, wherein the plurality of structures are provided on a light incident side of the semiconductor layer; and
a processing circuit that processes a generated image signal.

19. The electronic apparatus according to claim 18, wherein each of the plurality of light-guiding walls is taller than the color filters in a cross-sectional view.

20. The electronic apparatus according to claim 18, wherein a cross-section of the plurality of structures have a rectangular or triangular shape.
